(19) United States
(12) Patent Application Publication
(10) Pub. No.: US 2025/0351714 A1
(43) Pub. Date: Nov. 13, 2025

(54) DISPLAY DEVICE INCLUDING LIGHT BLOCKING AND LIGHT REFLECTION PATTERNS, METHOD OF MANUFACTURING THE SAME, AND ELECTRONIC DEVICE INCLUDING THE SAME

(71) Applicant: SAMSUNG DISPLAY CO., LTD., YONGIN-SI (KR)

(72) Inventor: JAEHUN LEE, Yongin-si (KR)

(21) Appl. No.: 19/010,690

(22) Filed: Jan. 6, 2025

(30) Foreign Application Priority Data
May 8, 2024 (KR) 10-2024-0060336

(51) Int. Cl. H10K 59/80; H10K 59/12

(52) U.S. Cl. CPC H10K 59/8792; H10K 59/1201

(57) ABSTRACT

A display device includes a substrate including a light emitting area including a first sub-light emitting area and a second sub-light emitting area adjacent to the first sub-light emitting area. A non-light emitting area is adjacent to the light emitting area. A light emitting element is disposed on the substrate and includes a first sub-light emitting element disposed in the first sub-light emitting area and a second sub-light emitting element disposed in the second sub-light emitting area. Light blocking patterns are disposed in the first sub-light emitting area on the light emitting element, and reflection patterns are disposed adjacent to the second sub-light emitting area on the light emitting element.

### CROSS-REFERENCE TO RELATED APPLICATION(S)

This application claims priority under 35 U.S.C. § 119 to Korean Patent Application No. 10-2024-0060336, filed on May 8, 2024, in the Korean Intellectual Property Office (KIPO), the entire disclosure of which is incorporated by reference herein.

### TECHNICAL FIELD

The present disclosure relates to a display device and, more specifically, to a display device including light blocking and light reflection patterns and a method of manufacturing the display device.

### DISCUSSION OF THE RELATED ART

As information technology develops, the importance of a display device as a medium for conveying information to a user has been emphasized. Accordingly, the use of the display device, such as a liquid crystal display (LCD) device, an organic light emitting diode (OLED) display device, a plasma display device, or the like, is increasing.

Such display devices may display an image with a wide viewing angle, or a viewing angle of the image displayed on the display device may be limited for security reasons or to reduce the image reflection phenomenon.

### SUMMARY

A display device includes a substrate including a light emitting area and a non-light emitting area adjacent to the light emitting area. The light emitting area includes a first sub-light emitting area and a second sub-light emitting area adjacent to the first sub-light emitting area. A light emitting element is disposed on the substrate and includes a first sub-light emitting element disposed in the first sub-light emitting area and a second sub-light emitting element disposed in the second sub-light emitting area. Light blocking patterns are disposed in the first sub-light emitting area on the light emitting element. Reflection patterns are disposed adjacent to the second sub-light emitting area on the light emitting element.

The light blocking patterns may overlap the first sub-light emitting area and the non-light emitting area in a plan view, and might not overlap the second sub-light emitting area in the plan view.

The reflection patterns might not overlap the first sub-light emitting area in a plan view, and may overlap the non-light emitting area in the plan view.

The reflection patterns may overlap an edge of the second sub-light emitting area in the plan view.

A distance between an adjacent pair of reflection patterns, of the reflection patterns, with the second sub-light emitting area interposed therebetween may be greater than or equal to a width of the second sub-light emitting area.

Each of the reflection patterns may contact a closest one of the light blocking patterns.

The display device may further include a transmission pattern covering the light blocking patterns and the reflection patterns.

The transmission pattern may include a first transmission pattern filling a space between the light blocking patterns disposed adjacent to each other and defining openings in which the reflection patterns are disposed and a second transmission pattern disposed on the first transmission pattern and filling the openings.

Each of the reflection patterns may at least partially cover side surfaces of a respective one of the openings.

A height of each of the reflection patterns may be less than or equal to a height of the first transmission pattern.

A level of an upper surface of each of the reflection patterns may be equal to a level of an upper surface of the first transmission pattern.

The light blocking patterns and the reflection patterns may include different materials.

The first sub-light emitting area and the second sub-light emitting area may emit light of a same wavelength band.

A method of manufacturing a display device includes forming a light emitting element on a substrate. The substrate includes a light emitting area including a first sub-light emitting area and a second sub-light emitting area adjacent to the first sub-light emitting area, and a non-light emitting area adjacent to the light emitting area. The light emitting element includes a first sub-light emitting element disposed in the first sub-light emitting area and a second sub-light emitting element disposed in the second sub-light emitting area. A transmission layer is formed on the light emitting element. The transmission layer is patterned to form a preliminary transmission pattern, the preliminary transmission pattern defining first openings in the first sub-light emitting area. Light blocking patterns are formed filling the first openings, respectively. The preliminary transmission pattern is patterned to form a first transmission pattern. The first transmission pattern defines a second opening in the second sub-light emitting area. Reflection patterns at least partially covering side surfaces of the second opening, respectively, are formed.

The light blocking patterns may overlap the first sub-light emitting area and the non-light emitting area and might not overlap the second sub-light emitting area, in a plan view.

The reflection patterns might not overlap the first sub-light emitting area and may overlap the non-light emitting area, in a plan view.

The reflection patterns may overlap an edge of the second sub-light emitting area, in the plan view.

A distance between an adjacent pair of the reflection patterns, with the second sub-light emitting area interposed therebetween, may be greater than or equal to a width of the second sub-light emitting area.

The reflection patterns may contact the light blocking pattern that are most adjacent, respectively.

A height of each of the reflection patterns may be less than or equal to a height of the first transmission pattern.

A level of an upper surface of each of the reflection patterns may be equal to a level of an upper surface of the first transmission pattern.

The method may further include forming a second transmission pattern filing the second opening and covering the light blocking patterns, the reflection patterns, and the first transmission pattern.

The first sub-light emitting area and the second sub-light emitting area may emit light of a same wavelength band.

An electronic device includes a display device and a power module that supplies power to the display device. The display device includes a substrate including a light emitting area and a non-light emitting area adjacent to the light emitting area. The light emitting area includes a first sub-light emitting area and a second sub-light emitting area adjacent to the first sub-light emitting area. A light emitting element is disposed on the substrate and includes a first sub-light emitting element disposed in the first sub-light emitting area and a second sub-light emitting element disposed in the second sub-light emitting area. Light blocking patterns are disposed in the first sub-light emitting area on the light emitting element. Reflection patterns are disposed adjacent to the second sub-light emitting area on the light emitting element.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a plan view illustrating a display device, according to an embodiment of the present disclosure.

FIG. 2 is an enlarged plan view illustrating a portion of a display area of the display device of FIG. 1.

FIG. 3 is a cross-sectional view taken along line I-I′ of FIG. 2.

FIGS. 4 and 5 are schematic views illustrating a viewing angle of the display device of FIG. 3.

FIGS. 6, 7, 8, and 9 are cross-sectional views illustrating an interval between reflection patterns of the display device of FIG. 3.

FIGS. 10, 11, 12, and 13 are cross-sectional views illustrating a height of a reflection pattern of the display device of FIG. 3.

FIGS. 14, 15, 16, 17, 18, 19, 20, and 21 are cross-sectional views illustrating a method of manufacturing a display device, according to an embodiment of the present disclosure.

FIGS. 22, 23, and 24 are cross-sectional views illustrating a method of manufacturing a display device, according to an embodiment of the present disclosure.

FIGS. 25, 26, 27, and 28 are cross-sectional views illustrating a method of manufacturing a display device, according to an embodiment of the present disclosure.

FIG. 29 is a diagram schematically illustrating an exterior of a vehicle, according to an embodiment of the present disclosure.

FIG. 30 is a diagram schematically illustrating an interior of the vehicle of FIG. 29.

FIG. 31 is a block diagram illustrating an electronic device, according to an embodiment of the present disclosure.

FIG. 32 is a schematic diagram of an electronic device, according to embodiments of the present disclosure.

### DETAILED DESCRIPTION OF THE EMBODIMENTS

Hereinafter, embodiments of the present disclosure will be described in more detail with reference to the accompanying drawings. The same reference numerals may be used for the same components in the drawings, and to the extent that an element is not described in detail with respect to this figure, it may be understood that the element is at least similar to a corresponding element that has been described elsewhere within the present disclosure.

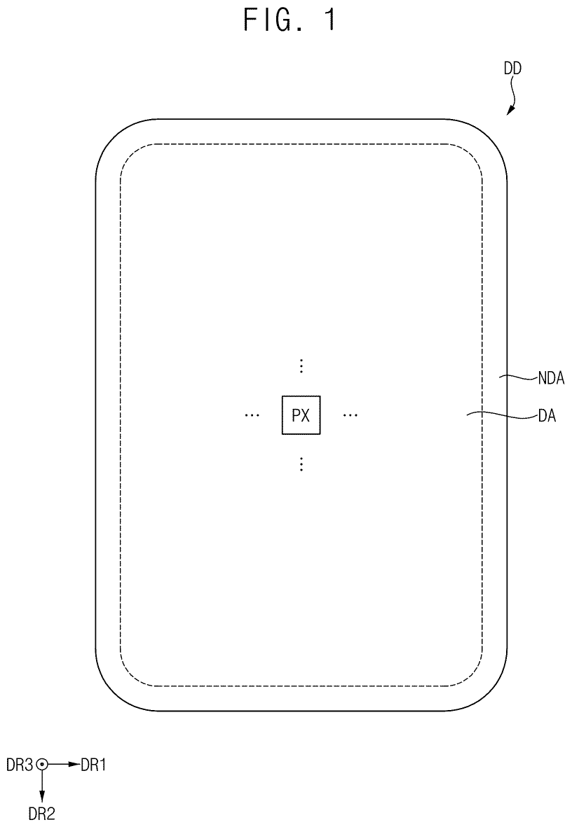

FIG. 1 is a plan view illustrating a display device, according to an embodiment of the present disclosure.

Referring to FIG. 1, a display device DD may include a display area DA and a non-display area NDA.

The display area DA may be an area that displays an image. Pixels PX may be disposed in the display area DA. The pixels PX may be repeatedly arranged along a first direction DR1 and a second direction DR2 intersecting the first direction DR1, in a plan view. For example, the second direction DR2 may be perpendicular to the first direction DR1. Each of the pixels PX may emit light, and accordingly, the display area DA may display an image.

The non-display area NDA may be an area that does not display an image. The non-display area NDA may be disposed proximate to the display area DA. For example, the non-display area NDA may surround the display area DA, on two or more sides, in a plan view. A driver may be disposed in the non-display area NDA. The driver may provide a signal or a voltage to the pixels PX. For example, the driver may include a data driver, a gate driver, a timing controller, or the like. The pixels PX may emit light based on the signal or the voltage received from the driver.

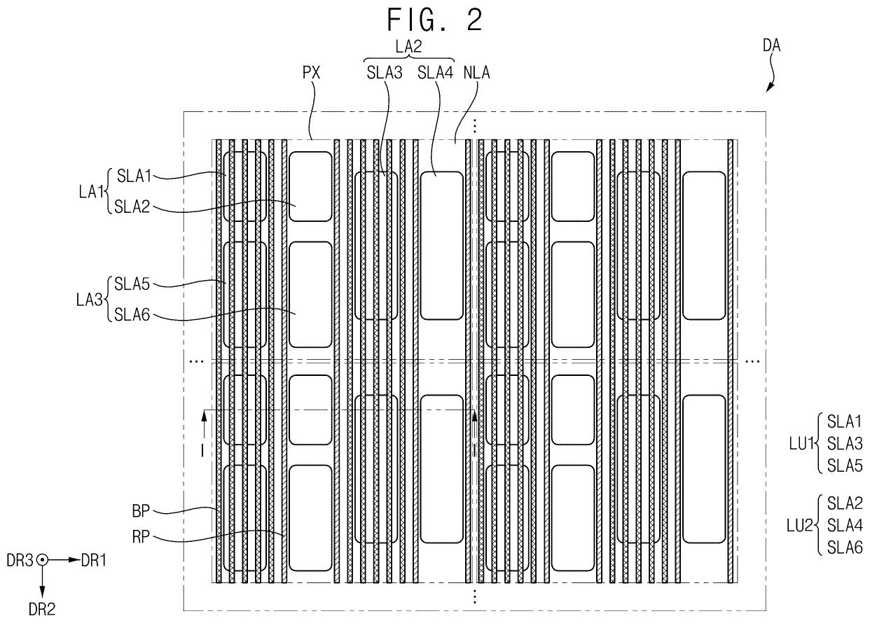

FIG. 2 is an enlarged plan view illustrating a portion of a display area of the display device of FIG. 1.

Referring to FIGS. 1 and 2, the display device DD may include the pixels PX, light blocking patterns BP, and reflection patterns RP disposed in the display area DA.

Each of the pixels PX may include a first light emitting area LA1, a second light emitting area LA2, a third light emitting area LA3, and a non-light emitting area NLA. Each of the first light emitting area LA1, the second light emitting area LA2, and the third light emitting area LA3 may be an area that emits light. The non-light emitting area NLA may be an area that does not emit light.

In an embodiment, each of the first light emitting area LA1, the second light emitting area LA2, and the third light emitting area LA3 may include a plurality of light emitting areas that are adjacent to each other. Each of the first light emitting area LA1, the second light emitting area LA2, and the third light emitting area LA3 may include two or more light emitting areas that are adjacent to each other.

The first light emitting area LA1 may include a first sub-light emitting area SLA1 and a second sub-light emitting area SLA2. The second sub-light emitting area SLA2 may be adjacent to the first sub-light emitting area SLA1 in one direction. In an embodiment, the second sub-light emitting area SLA2 may be adjacent to the first sub-light emitting area SLA1 in the first direction DR1. However, embodiments are not necessarily limited thereto, and in an embodiment, the second sub-light emitting area SLA2 may be adjacent to the first sub-light emitting area SLA1 in the second direction DR2.

The second light emitting area LA2 may include a third sub-light emitting area SLA3 and a fourth sub-light emitting area SLA4. The third sub-light emitting area SLA3 may be adjacent to the fourth sub-light emitting area SLA4 in one direction. In an embodiment, the fourth sub-light emitting area SLA4 may be adjacent to the third sub-light emitting area SLA3 in the first direction DR1. However, embodiments are not necessarily limited thereto, and in an embodiment, the fourth sub-light emitting area SLA4 may be adjacent to the third sub-light emitting area SLA3 in the second direction DR2.

The third light emitting area LA3 may include a fifth sub-light emitting area SLA5 and a sixth sub-light emitting area SLA6. The fifth sub-light emitting area SLA5 may be adjacent to the sixth sub-light emitting area SLA6 in one direction. In an embodiment, the sixth sub-light emitting area SLA6 may be adjacent to the fifth sub-light emitting area SLA5 in the first direction DR1. However, embodiments are not necessarily limited thereto, and in an embodiment, the sixth sub-light emitting area SLA6 may be adjacent to the fifth sub-light emitting area SLA5 in the second direction DR2.

In an embodiment, the first, second, and third light emitting areas LA1, LA2, and LA3 may emit light of different wavelength bands. The first light emitting area LA1 may emit first light, the second light emitting area LA2 may emit second light, and the third light emitting area LA3 may emit third light. The plurality of light emitting areas included in each of the first, second, and third light emitting areas LA1, LA2, and LA3 may emit light of substantially the same wavelength band. For example, each of the first and second sub-light emitting areas SLA1 and SLA2 may emit the first light, each of the third and fourth sub-light emitting areas SLA3 and SLA4 may emit the second light, and each of the fifth and sixth sub-light emitting areas SLA5 and SLA6 may emit the third light. For example, the first light may be light of a red wavelength band, the second light may be light of a blue wavelength band, and the third light may be light of a green wavelength band. However, embodiments are not necessarily limited thereto, and each of the first, second, and third light may be light of various wavelength bands. As the first, second, and third lights are combined, each of the pixels PX may emit light of various colors.

The red frequency band may be, for example, between 400 and 484 THz. The green frequency band may be, for example, between 526 and 606 THz. The blue frequency band may be, for example, between 606 and 668 THz.

The first sub-light emitting area SLA1, the third sub-light emitting area SLA3, and the fifth sub-light emitting area SLA5 may define a first light emitting portion LU1, and the second sub-light emitting area SLA2, the fourth sub-light emitting area SLA4, and the sixth sub-light emitting area SLA6 may define a second light emitting portion LU2. In an embodiment, the first light emitting portion LU1 and the second light emitting portion LU2 may emit light independently of each other. In each of the first, second, and third light emitting areas LA1, LA2, and LA3, when the first light emitting portion LU1 emits light, the second light emitting portion LU2 might not emit light, and when the second light emitting portion LU2 emits light, the first light emitting portion LU1 might not emit light.

For example, when the first sub-light emitting area SLA1 emits light, the second sub-light emitting area SLA2 might not emit light, and when the second sub-light emitting area SLA2 emits light, the first sub-light emitting area SLA1 might not emit light. When the third sub-light emitting area SLA3 emits light, the fourth sub-light emitting area SLA4 might not emit light, and when the fourth sub-light emitting area SLA4 emits light, the third sub-light emitting area SLA3 might not emit light. When the fifth sub-light emitting area SLA5 emits light, the sixth sub-light emitting area SLA6 might not emit light, and when the sixth sub-light emitting area SLA6 emits light, the fifth sub-light emitting area SLA5 might not emit light. However, embodiments are not necessarily limited thereto, and in an embodiment, in each of the first, second, and third light emitting areas LA1, LA2, and LA3, the first light emitting portion LU1 and the second light emitting portion LU2 may emit light simultaneously.

The non-light emitting area NLA may be disposed proximate to the first, second, and third light emitting areas LA1, LA2, and LA3. For example, the non-light emitting area NLA may surround the first, second, and third light emitting areas LA1, LA2, and LA3, in at least two sides, in a plan view. The non-light emitting area NLA may define the first, second, third, fourth, fifth, and sixth sub-light emitting areas SLA1, SLA2, SLA3, SLA4, SLA5, and SLA6.

Although FIG. 2 illustrates that the second light emitting area LA2 is adjacent to each of the first and third light emitting areas LA1 and LA3 in the first direction DR1, and the third light emitting area LA3 is adjacent to the first light emitting area LA1 in the second direction DR2, embodiments are not necessarily limited thereto. For example, the arrangement of the first, second, and third light emitting areas LA1, LA2, and LA3 may be variously changed, such as the first, second, and third light emitting areas LA1, LA2, and LA3 being arranged adjacent to each other along the first direction DR1.

In addition, although FIG. 2 illustrates that a planar area of the second light emitting area LA2 is larger than a planar area of each of the first and third light emitting areas LA1 and LA3, and a planar area of the third light emitting area LA3 is larger than a planar area of the first light emitting area LA1, embodiments are not necessarily limited thereto. For example, the planar area of each of the first, second, and third light emitting areas LA1, LA2, and LA3 may be variously changed, such as the planar area of the first light emitting area being substantially the same as the planar area of the second light emitting area.

In addition, although FIG. 2 illustrates that a planar area of the first sub-light emitting area SLA1 is substantially the same as a planar area of the second sub-light emitting area SLA2, a planar area of the third sub-light emitting area SLA3 is substantially the same as a planar area of the fourth sub-light emitting area SLA4, and a planar area of the fifth sub-light emitting area SLA5 is substantially the same as a planar area of the sixth sub-light emitting area SLA6, embodiments are not necessarily limited thereto. For example, the planar area of each of the first, second, third, fourth, fifth, and sixth sub-light emitting areas SLA1, SLA2, SLA3, SLA4, SLA5, and SLA6 may be variously changed, such as the planar areas of the first, third, and fifth sub-light emitting areas SLA1, SLA3, and SLA5 being larger than the planar areas of the second, fourth, and sixth sub-light emitting areas SLA2, SLA4, and SLA6, respectively.

The light blocking patterns BP may be disposed in at least one of the first light emitting portion LU1 and the non-light emitting area NLA, and might not be disposed in the second light emitting portion LU2. In a plan view, the light blocking patterns BP may overlap at least one of the first light emitting portion LU1 and the non-light emitting area NLA, and might not overlap the second light emitting portion LU2.

In an embodiment, the light blocking patterns BP may extend in the second direction DR2, respectively, and may be spaced apart from each other in the first direction DR1. For example, some of the light blocking patterns BP may extend in the second direction DR2 and overlap the first light emitting portion LU1 and the non-light emitting area NLA in a plan view, and the others of the light blocking patterns BP may extend in the second direction DR2 and overlap only the non-light emitting area NLA in a plan view.

The reflection patterns RP may be disposed adjacent to the second light emitting portion LU2. For example, the reflection patterns RP may be disposed in the non-light emitting area NLA adjacent to the second light emitting portion LU2, and might not be disposed in the first light emitting portion LU1. In a plan view, the reflection patterns RP may overlap the non-light emitting area NLA adjacent to the second light emitting portion LU2, and might not overlap the first light emitting portion LU1. For example, the reflection patterns RP may be disposed in the second light emitting portion LU2 and the non-light emitting area NLA, and might not be disposed in the first light emitting portion LU1. In this case, the reflection patterns RP may overlap an edge of the second light emitting portion LU2 in a plan view. For example, the reflection patterns RP may overlap a boundary between the non-light emitting area NLA and the second light emitting portion LU2 in a plan view.

In an embodiment, the reflection patterns RP may extend in the second direction DR2, respectively, and may be spaced apart from each other in the first direction DR1. For example, the reflection patterns RP may extend in the second direction DR2 and overlap at least one of the non-light emitting area NLA and the second light emitting portion LU2 in a plan view.

The light blocking patterns BP and the reflection patterns RP may be disposed along the first direction DR1. For example, the reflection patterns RP may be disposed between some of the light blocking patterns BP disposed in the first and fifth sub-light emitting areas SLA1 and SLA5 and others of the light blocking patterns BP disposed in the third sub-light emitting area SLA3. For example, the light blocking patterns BP may be disposed between some of the reflection patterns RP disposed adjacent to the second and sixth sub-light emitting areas SLA2 and SLA6 and the others of the reflection patterns RP disposed adjacent to the fourth sub-light emitting area SLA4.

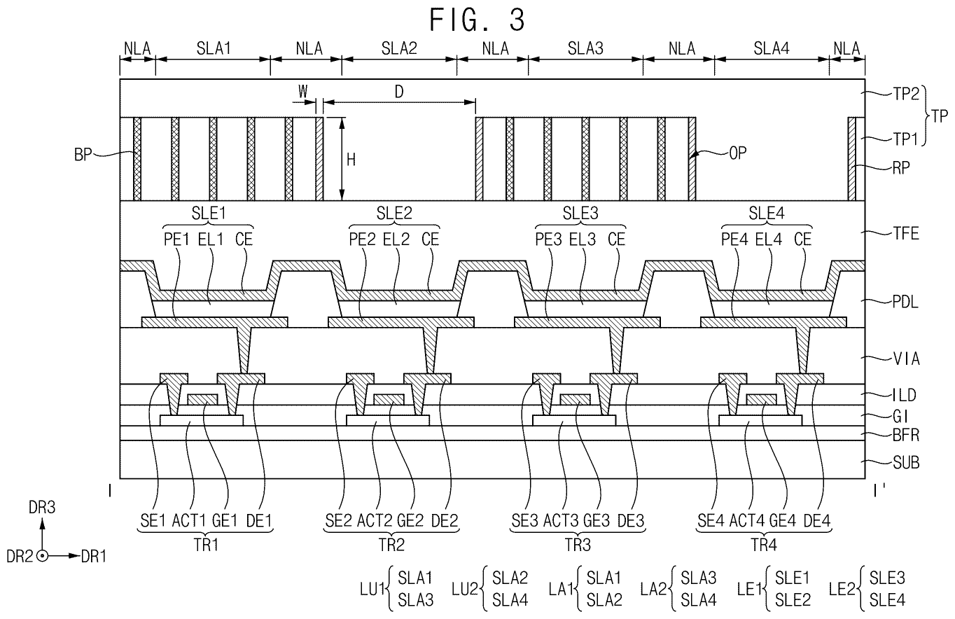

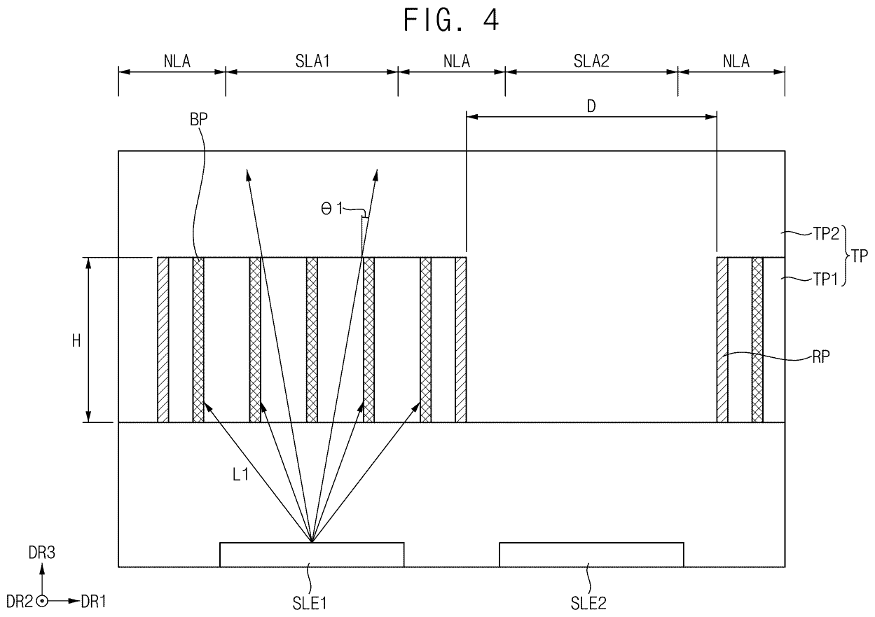

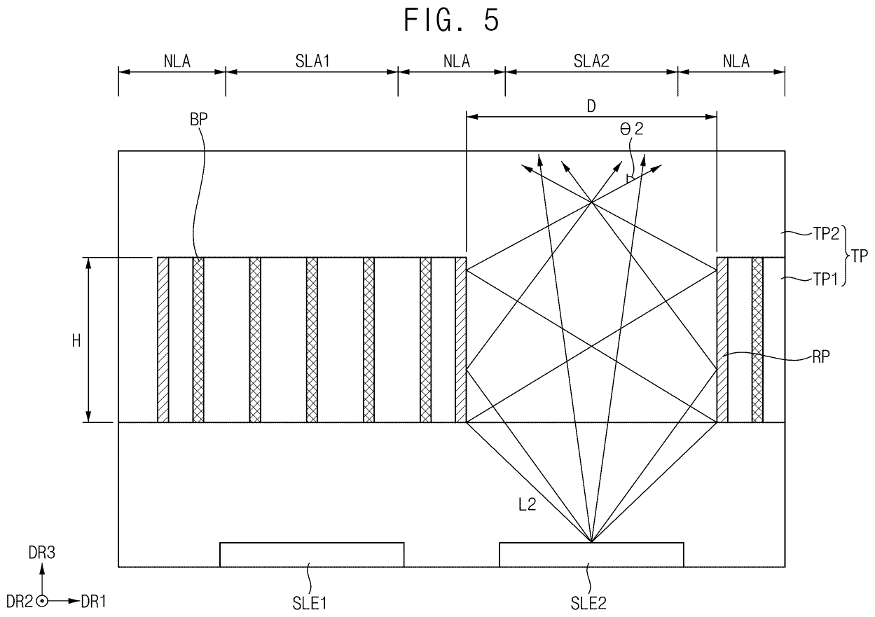

FIG. 3 is a cross-sectional view taken along line I-I′ of FIG. 2. FIGS. 4 and 5 are schematic views illustrating a viewing angle of the display device of FIG. 3.

Although FIG. 3 illustrates the first and second light emitting areas LA1 and LA2, it may also correspond to the third light emitting area LA3. In addition, although FIGS. 4 and 5 illustrate the first light emitting area LA1, it may also correspond to the second and third light emitting areas LA2 and LA3. For example, FIG. 4 may correspond to a case where the first light emitting portion LU1 (i.e., the first, third and fifth sub-light emitting areas SLA1, SLA3, and SLA5) emits light, and FIG. 5 may correspond to a case where the second light emitting portion LU2 (i.e., the second, fourth and sixth sub-light emitting areas SLA2, SLA4, and SLA6) emits light.

Referring to FIGS. 1, 2, 3, 4, and 5, the display device DD may include a substrate SUB, a buffer layer BFR, first, second, third, and fourth active patterns ACT1, ACT2, ACT3, and ACT4, a gate insulating layer GI, first, second, third, and fourth gate electrodes GE1, GE2, GE3, and GE4, an interlayer insulating layer ILD, first, second, third, and fourth source electrodes SE1, SE2, SE3, and SE4, first, second, third, and fourth drain electrodes DE1, DE2, DE3, and DE4, a via insulating layer VIA, first, second, third, and fourth pixel electrodes PE1, PE2, PE3, and PE4, a pixel defining layer PDL, first, second, third, and fourth light emitting layers EL1, EL2, EL3, and EL4, a common electrode CE, the light blocking patterns BP, the reflection patterns RP, and a transmission pattern TP.

The substrate SUB may include a transparent material or an opaque material. Examples of materials that may be used as the substrate SUB may include plastic, glass, quartz, or the like. These may be used alone or in combination with each other.

The buffer layer BFR may be disposed on the substrate SUB. The buffer layer BFR may prevent diffusion of metal atoms, impurities, or the like. In addition, the buffer layer BFR may increase a flatness of a surface of the substrate SUB when the surface of the substrate SUB is not uniform. The buffer layer BFR may include an inorganic material such as silicon oxide (SiOₓ), silicon nitride (SiNₓ), silicon oxynitride (SiOₓN_{y}), or the like. These may be used alone or in combination with each other.

The first, second, third, and fourth active patterns ACT1, ACT2, ACT3, and ACT4 may be disposed on the buffer layer BFR. Each of the first, second, third, and fourth active patterns ACT1, ACT2, ACT3, and ACT4 may include a source area, a drain area, and a channel area between the source area and the drain area. The first, second, third, and fourth active patterns ACT1, ACT2, ACT3, and ACT4 may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These may be used alone or in combination with each other.

The gate insulating layer GI may be disposed on the first, second, third, and fourth active patterns ACT1, ACT2, ACT3, and ACT4, and may cover the first, second, third, and fourth active patterns ACT1, ACT2, ACT3, and ACT4. The gate insulating layer GI may include an inorganic material such as silicon oxide, silicon nitride, silicon oxynitride, or the like. These may be used alone or in combination with each other.

The first, second, third, and fourth gate electrodes GE1, GE2, GE3, and GE4 may be disposed on the gate insulating layer GI. The first, second, third, and fourth gate electrodes GE1, GE2, GE3, and GE4 may overlap the channel areas of the first, second, third, and fourth active patterns ACT1, ACT2, ACT3, and ACT4, respectively, in a plan view. The first, second, third, and fourth gate electrodes GE1, GE2, GE3, and GE4 may include a metal, an alloy, a conductive metal oxide, a conductive metal nitride, a transparent conductive material, or the like. These may be used alone or in combination with each other.

The interlayer insulating layer ILD may be disposed on the first, second, third, and fourth gate electrodes GE1, GE2, GE3, and GE4, and may cover the first, second, third, and fourth gate electrodes GE1, GE2, GE3, and GE4. The interlayer insulating layer ILD may include an inorganic material such as silicon oxide, silicon nitride, silicon oxynitride, or the like. These may be used alone or in combination with each other.

The first, second, third, and fourth source electrodes SE1, SE2, SE3, and SE4 and the first, second, third, and fourth drain electrodes DE1, DE2, DE3, and DE4 may be disposed on the interlayer insulating layer ILD. The first, second, third, and fourth source electrodes SE1, SE2, SE3, and SE4 may be connected to the source areas of the first, second, third, and fourth active patterns ACT1, ACT2, ACT3, and ACT4 through contact holes penetrating the gate insulating layer GI and the interlayer insulating layer ILD, respectively. In addition, the first, second, third, and fourth drain electrodes DE1, DE2, DE3, and DE4 may be connected to the drain areas of the first, second, third, and fourth active patterns ACT1, ACT2, ACT3, and ACT4 through contact holes penetrating the gate insulating layer GI and the interlayer insulating layer ILD, respectively. For example, the first, second, third, and fourth source electrodes SE1, SE2, SE3, and SE4 and the first, second, third, and fourth drain electrodes DE1, DE2, DE3, and DE4 may include a metal, an alloy, a conductive metal oxide, a conductive metal nitride, a transparent conductive material, or the like. These may be used alone or in combination with each other.

The first active pattern ACT1, the first gate electrode GE1, the first source electrode SE1, and the first drain electrode DE1 may define a first transistor TR1, and the second active pattern ACT2, the second gate electrode GE2, the second source electrode SE2, and the second drain electrode DE2 may define a second transistor TR2. The third active pattern ACT3, the third gate electrode GE3, the third source electrode SE3, and the third drain electrode DE3 may define a third transistor TR3, and the fourth active pattern ACT4, the fourth gate electrode GE4, the fourth source electrode SE4, and the fourth drain electrode DE4 may define a fourth transistor TR4. Accordingly, the first, second, third, and fourth transistors TR1, TR2, TR3, and TR4 may be disposed on the substrate SUB.

The via insulating layer VIA may be disposed on the interlayer insulating layer ILD, and may cover the first, second, third, and fourth source electrodes SE1, SE2, SE3, and SE4 and the first, second, third, and fourth drain electrodes DE1, DE2, DE3, and DE4. The via insulating layer VIA may include an organic material such as a phenol resin, an acrylic resin, a polyimide resin, a polyamide resin, a siloxane resin, an epoxy resin, or the like. These may be used alone or in combination with each other.

The first, second, third, and fourth pixel electrodes PE1, PE2, PE3, and PE4 may be disposed on the via insulating layer VIA. The first, second, third, and fourth pixel electrodes PE1, PE2, PE3, and PE4 may overlap the first, second, third, and fourth sub-light emitting areas SLA1, SLA2, SLA3, and SLA4 in a plan view, respectively. The first, second, third, and fourth pixel electrodes PE1, PE2, PE3, and PE4 may be electrically connected to the first, second, third, and fourth transistors TR1, TR2, TR3, and TR4, respectively. For example, the first, second, third, and fourth pixel electrodes PE1, PE2, PE3, and PE4 may be connected to the first, second, third, and fourth drain electrodes DE1, DE2, DE3, and DE4 (or, the first, second, third, and fourth source electrodes SE1, SE2, SE3, and SE4) through contact holes penetrating the via insulating layer VIA, respectively. The first, second, third, and fourth pixel electrodes PE1, PE2, PE3, and PE4 may include a metal, an alloy, a conductive metal oxide, a conductive metal nitride, a transparent conductive material, or the like. These may be used alone or in combination with each other.

The pixel defining layer PDL may be disposed on the via insulating layer VIA. The pixel defining layer PDL may overlap the non-light emitting area NLA in a plan view. The pixel defining layer PDL may cover side portions of each of the first, second, third, and fourth pixel electrodes PE1, PE2, PE3, and PE4, and may define openings exposing a portion of an upper surface of each of the first, second, third, and fourth pixel electrodes PE1, PE2, PE3, and PE4. The pixel defining layer PDL may include an organic material such as a polyimide resin, an epoxy resin, a siloxane resin, or the like. These may be used alone or in combination with each other.

The first, second, third, and fourth light emitting layers EL1, EL2, EL3, and EL4 may be disposed on the first, second, third, and fourth pixel electrodes PE1, PE2, PE3, and PE4, respectively. The first, second, third, and fourth light emitting layers EL1, EL2, EL3, and EL4 may overlap the first, second, third, and fourth sub-light emitting areas SLA1, SLA2, SLA3, and SLA4 in a plan view, respectively. Each of the first, second, third, and fourth light emitting layers EL1, EL2, EL3, and EL4 may include a material that emits light of a predetermined color. For example, each of the first and second light emitting layers EL1 and EL2 may include a material that emits the first light, and the third and fourth light emitting layers EL3 and EL4 may include a material that emits the second light, but embodiments are not necessarily limited thereto.

The common electrode CE may be disposed on the first, second, third, and fourth light emitting layers EL1, EL2, EL3, and EL4 and the pixel defining layer PDL. For example, the common electrode CE may continuously extend in the first, second, and third light emitting areas LA1, LA2, and LA3 and the non-light emitting area NLA. The common electrode CE may include a metal, an alloy, a conductive metal oxide, a conductive metal nitride, a transparent conductive material, or the like. These may be used alone or in combination with each other.

The first and second pixel electrodes PE1 and PE2, the first and second light emitting layers EL1 and EL2, and the common electrode CE may define a first light emitting element LE1, and the third and fourth pixel electrodes PE3 and PE4, the third and fourth light emitting layers EL3 and EL4, and the common electrode CE may define a second light emitting element LE2. Accordingly, the first and second light emitting elements LE1 and LE2 may be disposed in the first and second light emitting areas LA1 and LA2 on the substrate SUB, respectively. The first and second light emitting elements LE1 and LE2 may define the first and second light emitting areas LA1 and LA2, respectively.

The first light emitting elements LE1 may include a first sub-light emitting element SLE1 and a second sub-light emitting element SLE2 that each emits light. The first pixel electrode PE1, the first light emitting layer EL1, and the common electrode CE may define the first sub-light emitting element SLE1, and the second pixel electrode PE2, the second light emitting layer EL2, and the common electrode CE may define the second sub-light emitting element SLE2. For example, the first and second sub-light emitting elements SLE1 and SLE2 may emit light of substantially the same wavelength band. For example, each of the first and second sub-light emitting elements SLE1 and SLE2 may emit the first light.

The second light emitting elements LE2 may include a third sub-light emitting element SLE3 and a fourth sub-light emitting element SLE4 that each emits light. The third pixel electrode PE3, the third light emitting layer EL3, and the common electrode CE may define the third sub-light emitting element SLE3, and the fourth pixel electrode PE4, the fourth light emitting layer EL4, and the common electrode CE may define the fourth sub-light emitting element SLE4. For example, the third and fourth sub-light emitting elements SLE3 and SLE4 may emit light of substantially the same wavelength band. For example, each of the third and fourth sub-light emitting elements SLE3 and SLE4 may emit the second light.

Accordingly, the first, second, third, and fourth sub-light emitting elements SLE1, SLE2, SLE3, and SLE4 may be disposed in the first, second, third, and fourth sub-light emitting areas SLA1, SLA2, SLA3, and SLE4 on the substrate SUB, respectively. The first, second, third, and fourth sub-light emitting elements SLE1, SLE2, SLE3, and SLE4 may define the first, second, third, and fourth sub-light emitting areas SLA1, SLE2, SLE3, and SLE4, respectively. The first, second, third, and fourth sub-light emitting elements SLE1, SLE2, SLE3, and SLE4 may be electrically connected to the first, second, third, and fourth transistors TR1, TR2, TR3, and TR4, respectively.

The encapsulation layer TFE may be disposed on the common electrode CE. The encapsulation layer TFE may prevent impurities, moisture, outside air, or the like from penetrating into the first and second light emitting elements LE1 and LE2 from the outside. In an embodiment, the encapsulation layer TFE may include at least one inorganic layer and at least one organic layer. For example, the organic layer and the inorganic layer may be alternately stacked.

The light blocking patterns BP may be disposed on the encapsulation layer TFE. In a plan view, the light blocking patterns BP may overlap the first light emitting portion LU1 and the non-light emitting area NLA, and might not overlap the second light emitting part LU2. For example, the light blocking patterns BP may be disposed on the first and third sub-light emitting elements SLE1 and SLE3.

The light blocking patterns BP may include a light blocking material (e.g., a material that absorbs light). For example, the light blocking patterns BP may include an organic material including a black pigment, a black dye, or the like. However, embodiments are not necessarily limited thereto, and the light blocking patterns BP may include various materials having relatively low transmittance and reflectance (e.g., transmittance below 30% or 20% or 10% transmittance/reflectance) and relatively high absorption (e.g., transmittance above 70% or 80% or 90% absorption).

First emitted light L1 emitted from the light emitting elements disposed in the first light emitting portion LU1 (i.e., the first, third, and fifth sub-light emitting elements SLE1, SLE3, and SLE5) may be incident on the light blocking patterns BP or may pass between the light blocking patterns BP. The light incident on the light blocking patterns BP may be reflected from the light blocking patterns BP, transmitted through the light blocking patterns BP, or absorbed by the light blocking patterns BP.

In an embodiment, most of the light incident on the light blocking patterns BP may be absorbed by the light blocking patterns BP. A first viewing angle θ1 of the first light emitting portion LU1 of the display device DD may be controlled by the light blocking patterns BP. Here, the first viewing angle θ1 may be defined as an angle formed by a user's gaze direction (i.e., a user's viewing direction) and a virtual straight line in the third direction DR3. For example, when the user views the display device DD in the third direction DR3 (i.e., a vertical direction), the first viewing angle θ1 may be about 0°. The first viewing angle θ1 of the first light emitting portion LU1 may be relatively narrow by the light blocking patterns BP (see FIG. 4).

The reflection patterns RP may be disposed on the encapsulation layer TFE. The reflection patterns RP may be disposed adjacent to the second light emitting portion LU2. In a plan view, the reflection patterns RP may overlap the non-light emitting area NLA, and might not overlap the first light emitting portion LU1. For example, the reflection patterns RP may be disposed on the second and fourth sub-light emitting elements SLE2 and SLE4.

A width W of the reflection pattern RP may be relatively small. The width W of the reflection pattern RP may be smaller than a width of the light blocking pattern BP. Here, the width W of the reflection pattern RP and the width of the light blocking pattern BP may be lengths of the reflection pattern RP and the light blocking pattern BP in the first direction DR1, respectively. For example, the width W of the reflection pattern RP may be about 1 μm or less, but embodiments are not necessarily limited thereto.

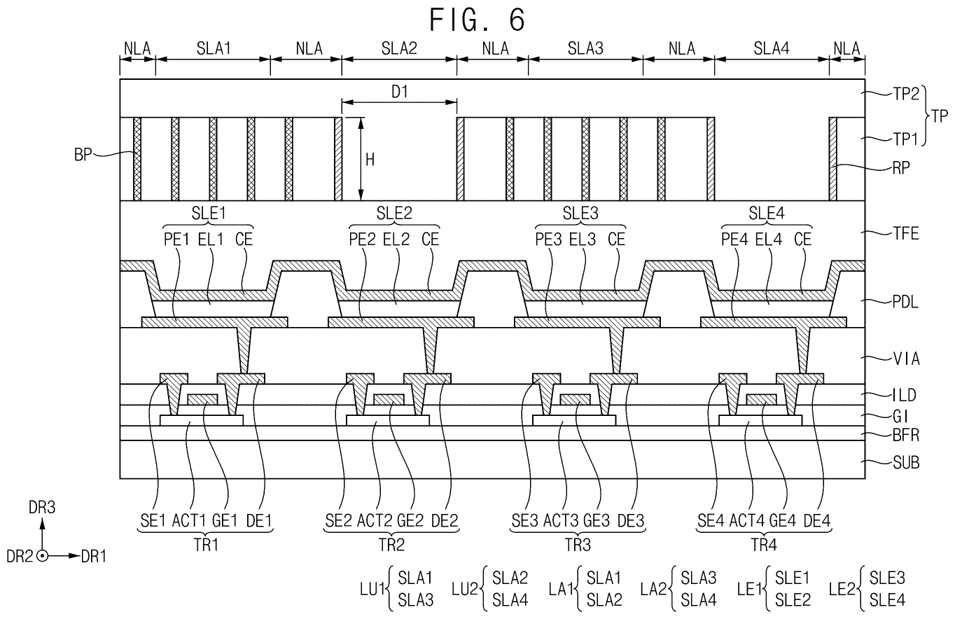

A distance D between the reflection patterns RP disposed adjacent to each other with the second light emitting portion LU2 interposed therebetween may be variously changed. A detailed description thereof will be described later with reference to FIGS. 6, 7, 8, and 9. Here, the distance D between the reflection patterns RP may be a length in the first direction DR1 between the reflection patterns RP adjacent to each other with the second light emitting portion LU2 interposed therebetween. For example, the distance D may be a length in the first direction DR1 between the reflection patterns RP adjacent to each other without the light blocking patterns BP interposed therebetween. For example, the distance D may be an average of a distance between side surfaces of the reflection patterns RP adjacent to the light blocking patterns BP and a distance between side surfaces of the reflection patterns RP spaced apart from the light blocking patterns BP. The distance D between the reflection patterns RP adjacent to each other with the second light emitting portion LU2 interposed therebetween may be greater than a distance between the light blocking patterns BP adjacent to each other with the first light emitting portion LU1 interposed therebetween.

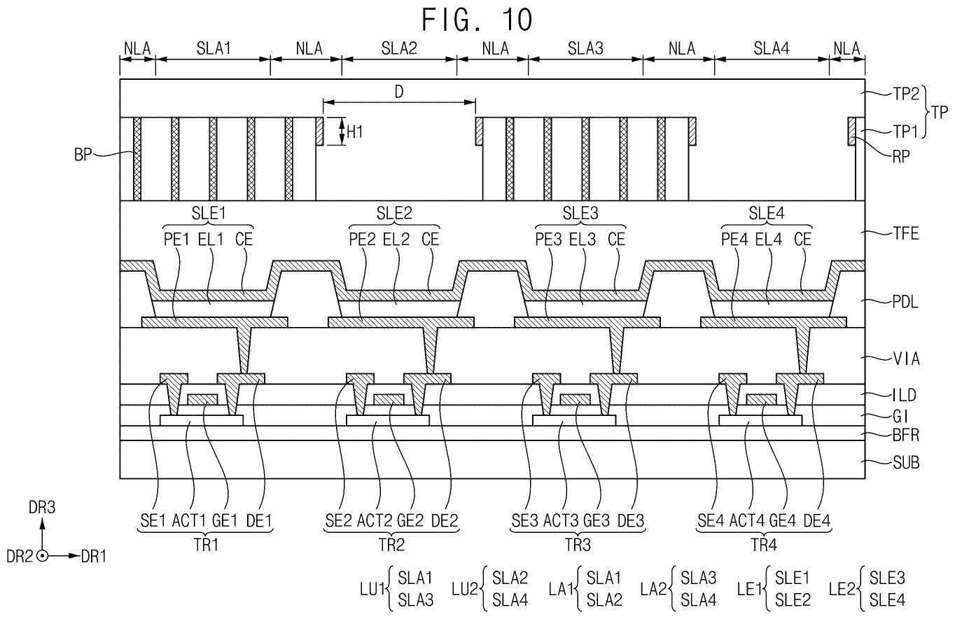

A height H of the reflection pattern RP may be variously changed. A detailed description thereof will be described later with reference to FIGS. 10, 11, 12, and 13. Here, the height H of the reflection pattern RP may be a length of the reflection pattern RP in the third direction DR3.

The reflection patterns RP may include a material different from that of the light blocking patterns BP. The reflection patterns RP may include a material that reflects light. For example, the reflection patterns RP may include a metal such as silver (Ag), aluminum (Al), or the like. However, embodiments are not necessarily limited thereto, and the reflection patterns RP may include various materials having relatively low transmittance and absorption and relatively high reflectance.

Second emitted light L2 emitted from the light emitting elements disposed in the second light emitting portion LU2 (i.e., the second, fourth, and sixth sub-light emitting elements SLE2, SLE4, and SLE6) may be incident on the reflection patterns RP or may pass between the reflection patterns RP. The light incident on the reflection patterns RP may be reflected by the reflection patterns RP, transmitted through the reflection patterns RP, or absorbed by the reflection patterns RP.

In an embodiment, most of the light incident on the reflection patterns RP may be reflected from the reflection patterns RP. A second viewing angle θ2 of the second light emitting portion LU2 of the display device DD may be controlled by the reflection patterns RP. Here, the second viewing angle θ2 may be defined as an angle formed by a user's gaze direction and a virtual straight line in the third direction DR3. The second viewing angle θ2 of the second light emitting portion LU2 may be relatively wide by the reflection patterns RP (see FIG. 5).

The transmission pattern TP may be disposed on the encapsulation layer TFE. The transmission pattern TP may cover the light blocking patterns BP and the reflection patterns RP. The transmission pattern TP may include an organic material such as an epoxy resin, a siloxane resin, a polyimide resin, a photoresist, or the like. The transmission pattern TP may be optically transparent. Light emitted from the first and second light emitting elements LE1 and LE2 and incident on the transmission pattern TP may transmit through the transmission pattern TP. The transmission pattern TP may include a material having a relatively low refractive index. For example, the transmission pattern TP may include a material having a refractive index of about 1.5 or less, but embodiments are not necessarily limited thereto. The transmission pattern TP may have a single-layer structure or a multi-layer structure. For example, the transmission pattern TP may include a first transmission pattern TP1 and a second transmission pattern TP2.

The first transmission pattern TP1 may fill a space between the light blocking patterns BP adjacent to each other. The first transmission pattern TP1 may cover side surfaces of the light blocking patterns BP. The first transmission pattern TP1 may define openings OP in which the reflection patterns RP are disposed. In a plan view, the openings OP may overlap the second light emitting portion LU2, and might not overlap the first light emitting portion LU1. Side surfaces of the openings OP may be at least partially covered by the reflection patterns RP, respectively. For example, the side surfaces of the openings OP may at least partially contact the reflection patterns RP, respectively. In addition, the first transmission pattern TP1 may further fill a space between the light blocking pattern BP and the reflection pattern RP adjacent to each other. The first transmission pattern TP1 may cover side surfaces of the reflection patterns RP adjacent to the light blocking patterns BP. In an embodiment, a level of an upper surface of the first transmission pattern TP1 may be substantially equal to or similar to a level of upper surfaces of the reflection patterns RP.

The second transmission pattern TP2 may fill the openings OP, and may be disposed on the first transmission pattern TP1. The second transmission pattern TP2 may fill a space between the reflection patterns RP adjacent to each other, and may cover the light blocking patterns BP, the reflection patterns RP, and the first transmission pattern TP1. The second transmission pattern TP2 may cover side surfaces of the reflection patterns RP spaced apart from the light blocking patterns BP. The second transmission pattern TP2 may overlap the first, second, and third light emitting areas LA1, LA2, and LA3 and the non-light emitting area NLA in a plan view.

For example, the first transmission pattern TP1 and the second transmission pattern TP2 may include different materials. In this case, a refractive index of the material included in the first transmission pattern TP1 may be substantially equal to or similar to a refractive index of the material included in the second transmission pattern TP2. For example, the first transmission pattern TP1 and the second transmission pattern TP2 may include the same material.

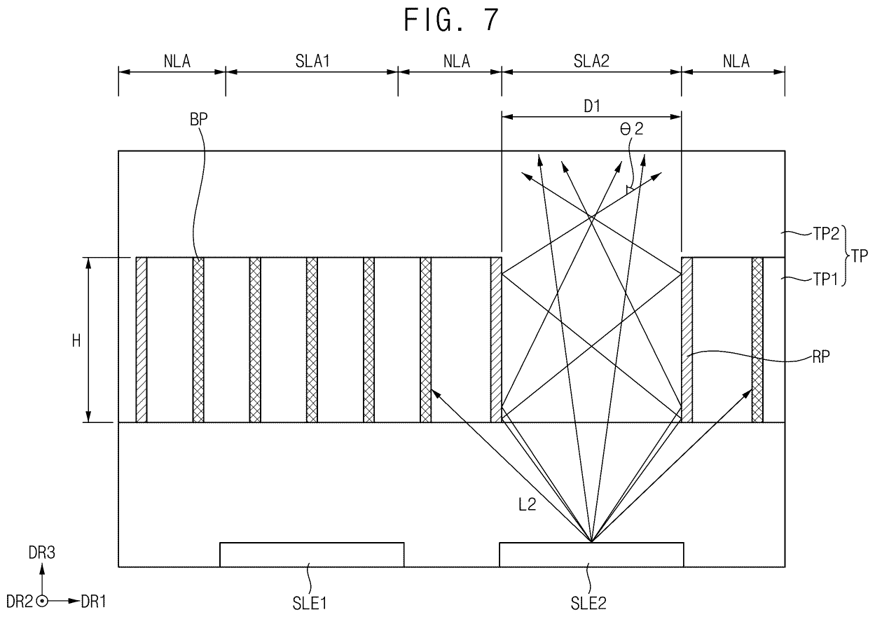

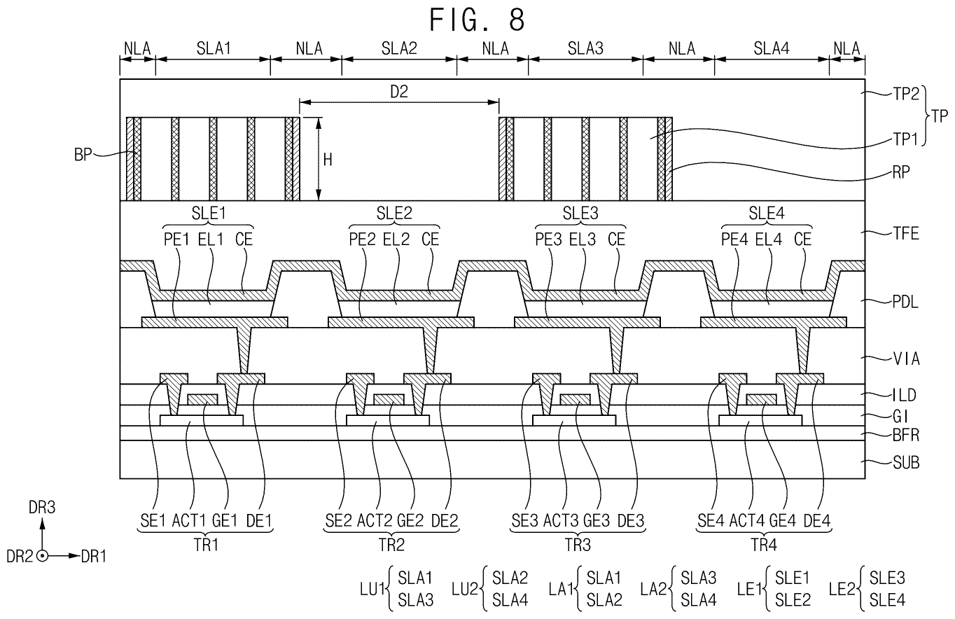

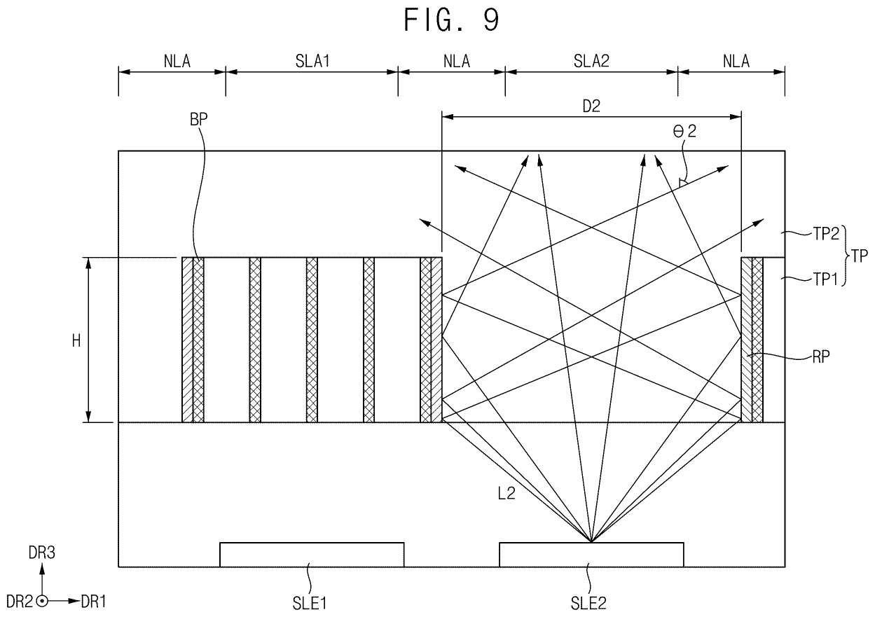

FIGS. 6, 7, 8, and 9 are cross-sectional views illustrating a distance between reflection patterns of the display device of FIG. 3. FIGS. 6 and 8 may respectively correspond to the cross-sectional view of FIG. 3, and FIGS. 7 and 9 may respectively correspond to the cross-sectional view of FIG. 5.

Referring to FIGS. 2, 6, and 7, the reflection patterns RP may overlap the edge of the second light emitting portion LU2 (i.e., the second, fourth, and sixth sub-light emitting areas SLA2, SLA4, and SLA6) in a plan view. The reflection patterns RP may overlap the boundary between the second light emitting portion LU2 and the non-light emitting area NLA in a plan view.

In an embodiment, the reflection patterns RP disposed adjacent to each other with the second light emitting portion LU2 interposed therebetween may be spaced apart from each other by a first distance D1. The first distance DI may be substantially equal to as or similar to a width of the second light emitting portion LU2. Here, the width of the second light emitting portion LU2 may be a length of the second light emitting portion LU2 in the first direction DR1.

When the reflection patterns RP are spaced apart from each other by the first distance D1, light incident on the reflection patterns RP among the second emitted light L2 emitted from the light emitting elements disposed in the second light emitting portion LU2 may be reduced. For example, a portion of the second emitted light L2 having a relatively large light emitting angle might not be incident on the reflection patterns RP or might not pass between the reflection patterns RP, but may be incident on the light blocking patterns BP. Since light incident on the light blocking patterns BP among the second emitted light L2 may be absorbed by the light blocking patterns BP, light incident on the reflection patterns RP among the second emitted light L2 may be reduced. Accordingly, luminance of the second light emitting portion LU2 of the display device DD may be reduced.

In addition, when the reflection patterns RP are spaced apart from each other by the first distance D1, an incident angle of light incident on the reflection patterns RP among the second emitted light L2 may be reduced (i.e., small). Accordingly, the second viewing angle θ2 of the second light emitting portion LU2 of the display device DD may be narrowed (see FIG. 7).

Referring to FIGS. 2, 7, 8, and 9, in a plan view, the reflection patterns RP may overlap the non-light emitting area NLA, and might not overlap the second light emitting portion LU2.

In an embodiment, the reflection patterns RP adjacent to each other with the second light emitting portion LU2 interposed therebetween may be spaced apart from each other by a second distance D2. The second distance D2 may be greater than the first distance D1. The second distance D2 may be a distance between the reflection patterns RP adjacent to each other when the reflection patterns RP contact the light blocking patterns BP. The reflection patterns RP may contact the light blocking patterns BP that are most adjacent (i.e. the closest light blocking patterns BP), respectively. The reflection patterns RP may contact the light blocking patterns BP that are most distant from a center of the first light emitting portion LU1 in a plan view, respectively. A side surface adjacent to the light blocking pattern BP of each of the reflection patterns RP may contact at least a portion of a side surface of the light blocking pattern BP. Each of the reflection patterns RP may at least partially cover the side surface of the light blocking pattern BP.

When the reflection patterns RP are spaced apart from each other by the second distance D2, light incident on the reflection patterns RP among the second emitted light L2 emitted from the light emitting elements disposed in the second light emitting portion LU2 may be increased. For example, a portion of the second emitted light L2 having a relatively large light emitting angle may also be incident on the reflection patterns RP. Since light incident on the reflection patterns RP among the second emitted light L2 may be reflected and emitted from the reflection patterns RP, light incident on the light blocking patterns BP among the second emitted light L2 may be reduced. Accordingly, the luminance of the second light emitting portion LU2 of the display device DD may be increased.

In addition, when the reflection patterns RP are spaced apart from each other by the second distance D2, an incident angle of light incident on the reflection patterns RP among the second emitted light L2 may be increased (i.e., large). Accordingly, the second viewing angle θ2 of the second light emitting portion LU2 of the display device DD may be widened (see FIG. 9).

Referring to FIGS. 1 to 9, the luminance and the second viewing angle θ2 of the second light emitting portion LU2 of the display device DD may be controlled by the distance D between the reflection patterns RP. As the distance D between the reflection patterns RP decreases, the luminance of the second light emitting portion LU2 may decrease and the second viewing angle θ2 of the second light emitting portion LU2 may be narrowed. In addition, as the distance D between the reflection patterns RP increases, the luminance of the second light emitting portion LU2 may increase and the second viewing angle θ2 of the second light emitting portion LU2 may be widened.

In an embodiment, in order to secure luminance and viewing angle of the second light emitting portion LU2, the first distance D1 may be defined as a minimum value of the distance D, and the second distance D2 may be defined as a maximum value of the distance D. For example, the distance D may be greater than or equal to the width of the second light emitting portion LU2, and may be less than or equal to a distance between the light blocking patterns BP spaced apart from each other with the second light emitting portion LU2 interposed therebetween. The distance D may be variously changed depending on a required viewing angle, a purpose, or the like of the display device DD within a range between the first distance DI and the second distance D2.

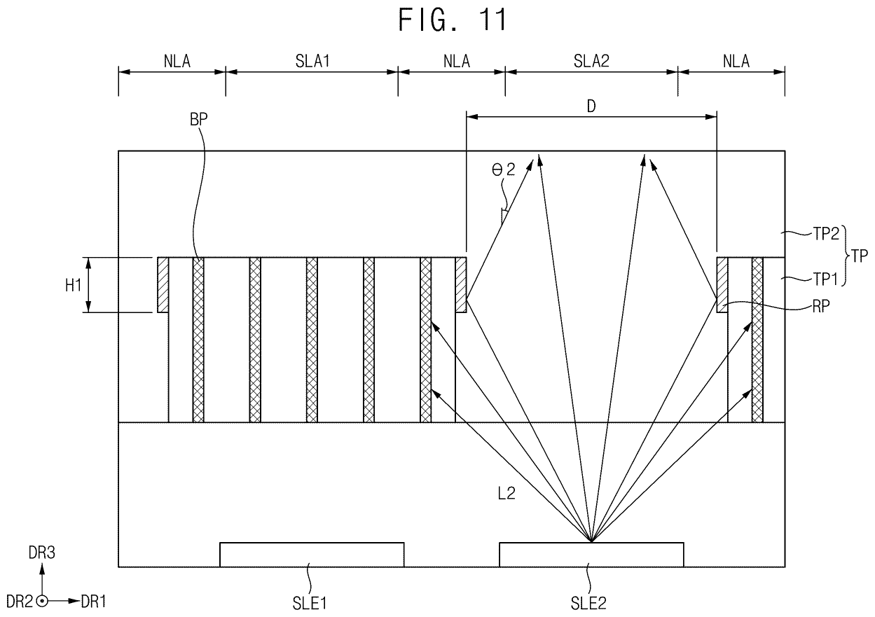

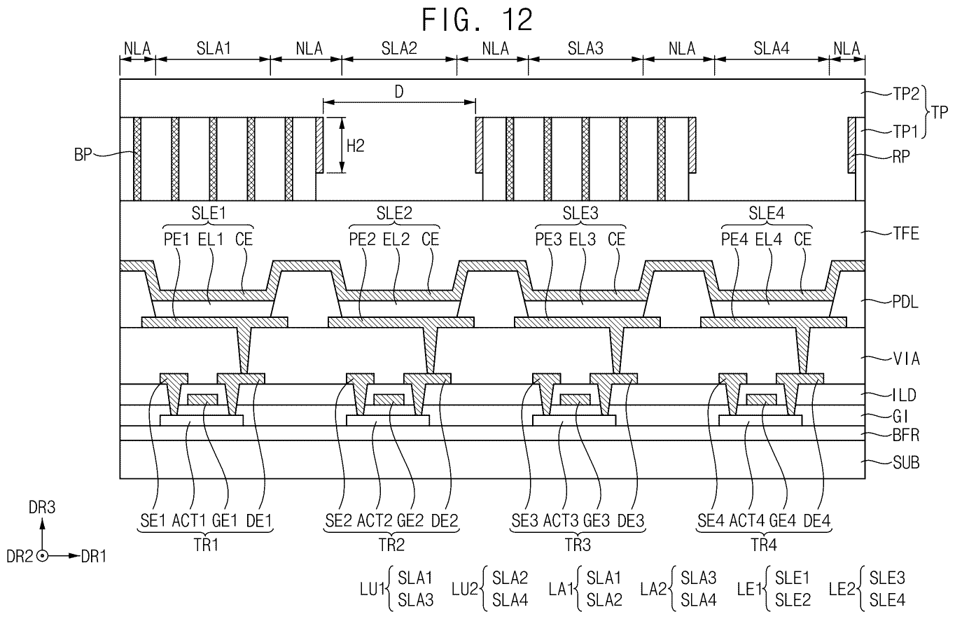

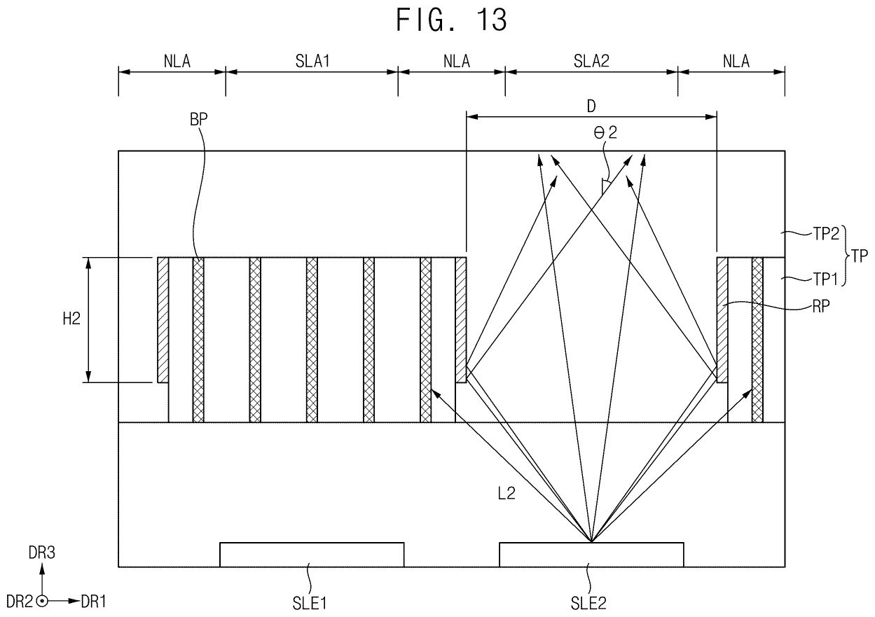

FIGS. 10, 11, 12, and 13 are cross-sectional views illustrating a height of a reflection pattern of the display device of FIG. 3. FIGS. 10 and 12 may respectively correspond to the cross-sectional view of FIG. 3, and FIGS. 11 and 13 may respectively correspond to the cross-sectional view of FIG. 5.

Referring to FIGS. 2, 10, and 11, the reflection pattern RP may have a first height H1. For example, the reflection pattern RP may have the first height H1 from the upper surface of the first transmission pattern TP1.

The first height H1 may be relatively small. For example, the reflection pattern RP may at least partially cover an upper side of a side surface of the first transmission pattern TP1 disposed between the reflection pattern RP and the light blocking pattern BP adjacent to each other. For example, when the reflection pattern RP contacts the light blocking pattern BP, the reflection pattern RP may at least partially cover an upper side of a side surface of the light blocking pattern BP.

When the reflection pattern RP has the first height H1, among the second emitted light L2 emitted from the light emitting elements disposed in the second light emitting portion LU2, light incident on the reflection patterns RP may be reduced, and light incident on the light blocking patterns BP may be increased. For example, among the second emitted light L2, only a portion having a relatively small light emitting angle may be incident on the reflection patterns RP, and another portion having a relatively large light emitting angle may be incident on the light blocking patterns BP. Since light incident on the light blocking patterns BP among the second emitted light L2 may be absorbed by the light blocking patterns BP, light incident on the reflection patterns RP among the second emitted light L2 may be reduced. Accordingly, the luminance of the second light emitting portion LU2 of the display device DD may be reduced.

In addition, when the reflection pattern RP has the first height H1, an incident angle of light incident on the reflection patterns RP among the second emitting light L2 may be reduced. Accordingly, the second viewing angle θ2 of the second light emitting portion LU2 of the display device DD may be narrowed (see FIG. 11).

Referring to FIGS. 2, 11, 12, and 13, the reflection pattern RP may have a second height H2. For example, the reflection pattern RP may have the second height H2 from the upper surface of the first transmission pattern TP1.

The second height H2 may be greater than the first height H1. For example, the reflection pattern RP may at least partially cover an upper side and a lower side of the side surface of the first transmission pattern TP1 disposed between the reflection pattern RP and the light blocking pattern BP adjacent to each other. For example, when the reflection pattern RP contacts the light blocking pattern BP, the reflection pattern RP may at least partially cover an upper side and a lower side of the side surface of the light blocking pattern BP.

When the reflection pattern RP has the second height H2, among the second emitted light L2 emitted from the light emitting elements disposed in the second light emitting portion LU2, light incident on the light blocking patterns BP may be reduced, and light incident on the reflection patterns RP may be increased. For example, among the second emitted light L2, only a portion having a relatively large light emitting angle may be incident on the light blocking patterns BP, and another portion having a relatively small light emitting angle may be incident on the reflection patterns RP. Since light incident on the reflection patterns RP among the second emitted light L2 may be reflected and emitted from the reflection patterns RP, light incident on the light blocking patterns BP among the second emitted light L2 may be reduced. Accordingly, the luminance of the second light emitting portion LU2 of the display device DD may be increased.

In addition, when the reflection pattern RP has the second height H2, an incident angle of light incident on the reflection patterns RP among the second emitted light L2 may be increased. Accordingly, the second viewing angle θ2 of the second light emitting portion LU2 of the display device DD may be widened (see FIG. 13).

Referring to FIGS. 1 to 5, and 10 to 13, the luminance and the second viewing angle θ2 at the second light emitting portion LU2 of the display device DD may be controlled by the height H of the reflection pattern RP. As the height H of the reflection pattern RP decreases, the luminance of the second light emitting portion LU2 may decrease and the second viewing angle θ2 of the second light emitting portion LU2 may be narrowed. In addition, as the height H of the reflection pattern RP increases, the luminance of the second light emitting portion LU2 may increase and the second viewing angle θ2 of the second light emitting portion LU2 may be widened.

In an embodiment, a maximum value of the height H may be defined as a height of the first transmission pattern TP1 or a height of the light blocking pattern BP. Here, the height of the first transmission pattern TP1 and the height of the light blocking pattern BP may be lengths of the first transmission pattern TP1 and the light blocking pattern BP in the third direction DR3, respectively. For example, the height H may be less than or equal to the height of the first transmission pattern TP1 or the light blocking pattern BP. The height H may be variously changed depending on a required viewing angle, a purpose, or the like of the display device DD within a range less than or equal to the height of the first transmission pattern TP1 or the light blocking pattern BP.

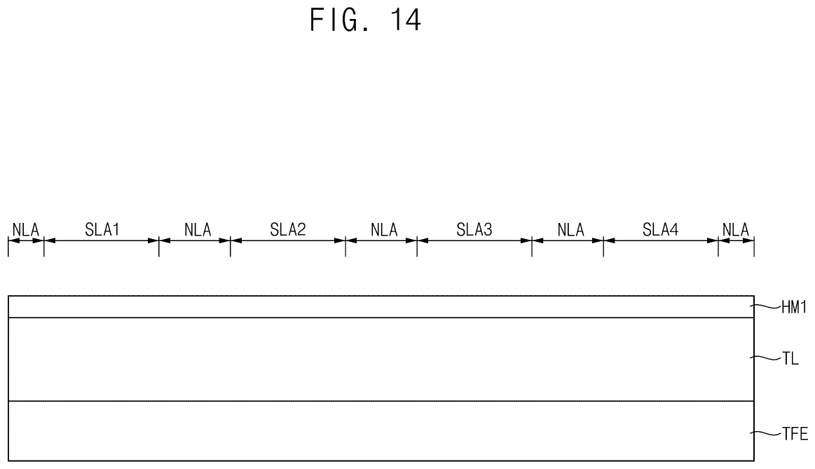

The display device DD, according to an embodiment of the present disclosure, may include the pixels PX each including the first light emitting portion LU1 and the second light emitting portion LU2. The light blocking patterns BP may be disposed in the first light emitting portion LU1, and the reflection patterns RP may be disposed adjacent to the second light emitting portion LU2. The light blocking patterns BP may absorb light emitted from the first light emitting portion LU1, and the reflection patterns RP may reflect and emit the light emitted from the second light emitting portion LU2. Accordingly, in each of the pixels PX, a viewing angle of the first light emitting portion LU1 may be controlled, and viewing angle and luminance of the second light emitting portion LU2 may be secured. Accordingly, a viewing angle of the display device DD may be effectively controlled, and light efficiency of the display device DD may be increased. FIGS. 14, 15, 16, 17, 18, 19, 20, and 21 are cross-sectional views illustrating a method of manufacturing a display device, according to an embodiment of the present disclosure. A method of manufacturing a display device described with reference to FIGS. 14 to 21 may be a method of manufacturing the display device DD described with reference to FIGS. 1 to 13. Hereinafter, to the extent that an element is not described in detail with respect to this figure, it may be understood that the element is at least similar to a corresponding element that has been described elsewhere within the present disclosure.

Referring to FIGS. 3 and 14, a transmission layer TL and a first hard mask HM1 may be sequentially formed on the encapsulation layer TFE.

The transmission layer TL may include an organic material, and may be optically transparent. In addition, the transmission layer TL may include a material having a relatively low refractive index. For example, the transmission layer TL may be formed through an inkjet process. For example, the first hard mask HM1 may include a metal, a transparent conductive material, an inorganic material, or the like.

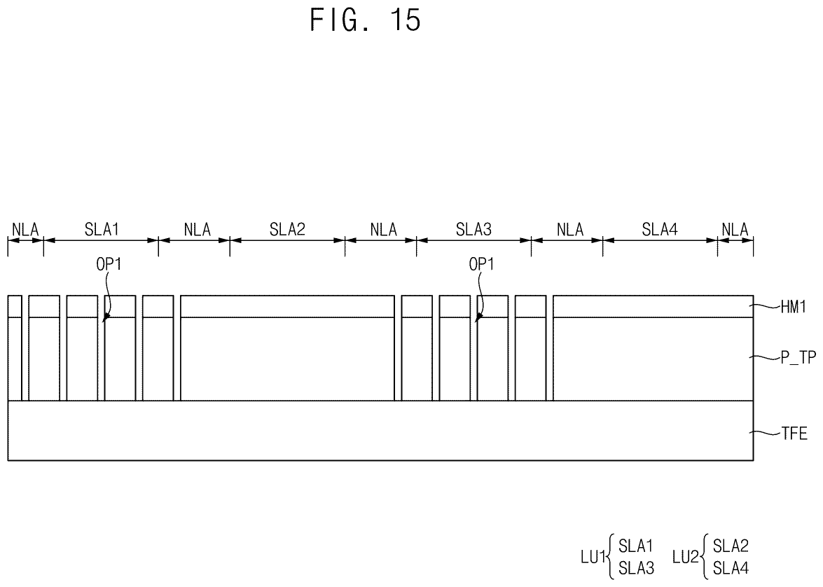

Referring to FIGS. 14 and 15, the first hard mask HM1 and the transmission layer TL may be patterned. For example, the first hard mask HM1 and the transmission layer TL may be patterned simultaneously by a photolithography process.

As the first hard mask HM1 and the transmission layer TL are etched, a preliminary transmission pattern P_TP may be formed. For example, the preliminary transmission pattern P_TP may be formed by a dry etching process. The preliminary transmission pattern P_TP may define first openings OP1 spaced apart from each other. Each of the first openings OP1 may penetrate the preliminary transmission pattern P_TP in a thickness direction of the preliminary transmission pattern P_TP. In a plan view, the first openings OP1 may overlap the first light emitting portion LU1 and the non-light emitting area NLA, and might not overlap the second light emitting portion LU2.

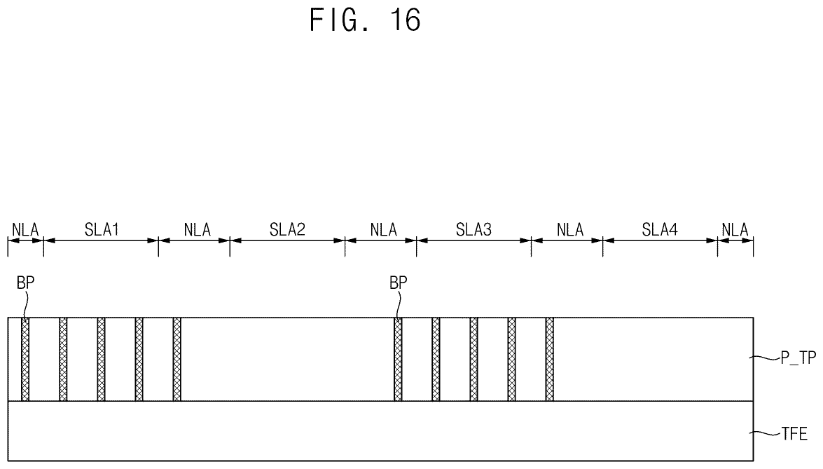

Referring to FIGS. 15 and 16, the first hard mask HM1 may be removed, and the preliminary transmission pattern P_TP may be exposed. For example, the first hard mask HM1 may be removed by a dry etching process or a wet etching process.

Thereafter, the light blocking patterns BP may be formed in the first openings OP1. For example, a light blocking layer including a light blocking material may fill the first openings OP1 and cover an upper surface of the preliminary transmission pattern P_TP, and the light blocking layer formed on the upper surface of the preliminary transmission pattern P_TP may be removed through a chemical mechanical polishing (CMP) process to form the light blocking patterns BP.

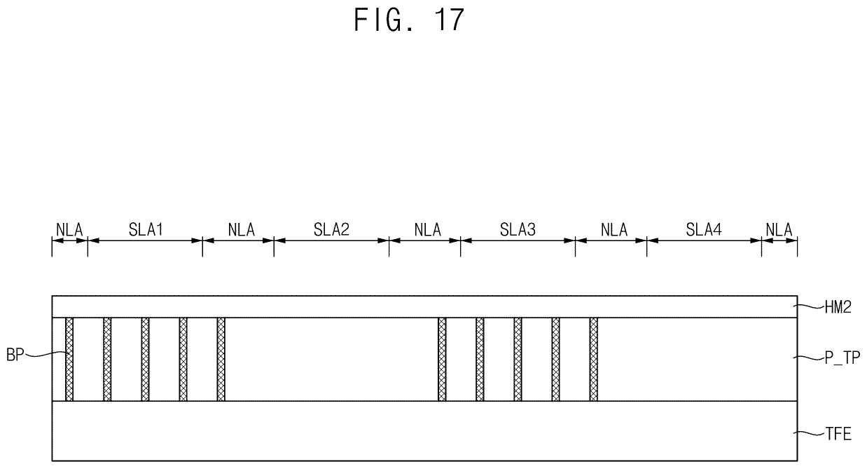

Referring to FIGS. 16 and 17, a second hard mask HM2 may be formed on the preliminary transmission pattern P_TP and the light blocking patterns BP. For example, the second hard mask HM2 may include a metal, a transparent conductive material, an inorganic material, or the like.

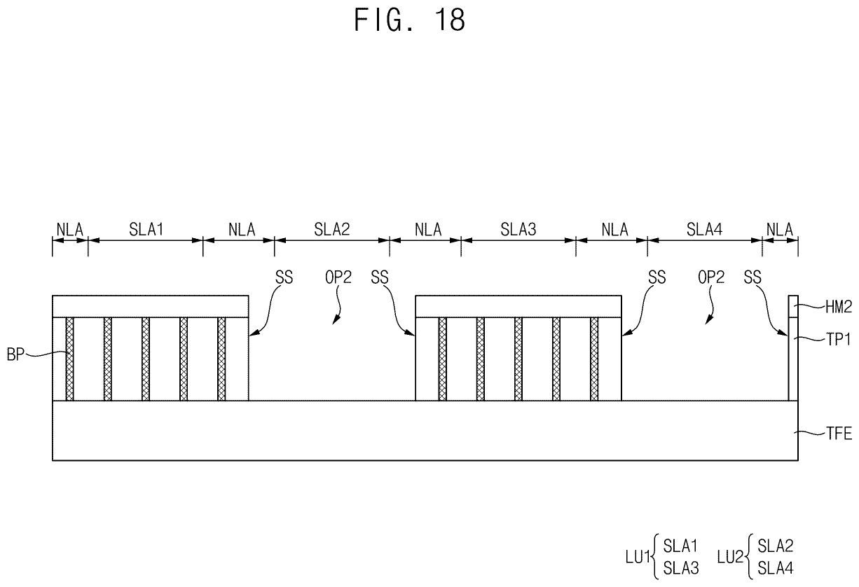

Referring to FIGS. 17 and 18, the second hard mask HM2 and the preliminary transmission pattern P_TP may be patterned. For example, the second hard mask HM2 and the preliminary transmission pattern P_TP may be patterned simultaneously by a photolithography process.

As the second hard mask HM2 and the preliminary transmission pattern P_TP are etched, the first transmission pattern TP1 may be formed. For example, the first transmission pattern TP1 may be formed through a dry etching process. The first transmission pattern TP1 may define second openings OP2 spaced apart from each other. In an embodiment, each of the second openings OP2 may penetrate the first transmission pattern TP1 in a thickness direction of the first transmission pattern TP1. In a plan view, the second openings OP2 may overlap the second light emitting portion LU2, and might not overlap the first light emitting portion LU1. The second openings OP2 may further overlap the non-light emitting area NLA in a plan view. For example, the second openings OP2 may correspond to the openings OP of FIG. 3.

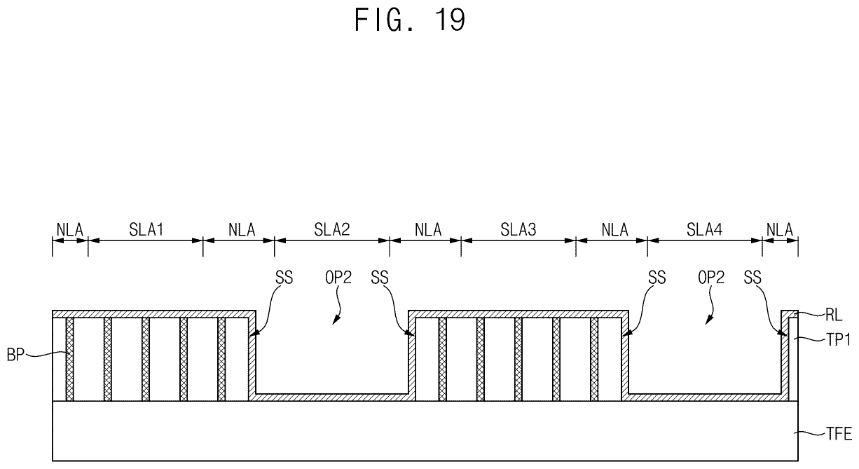

Referring to FIGS. 18 and 19, the second hard mask HM2 may be removed, and the light blocking patterns BP and the first transmission pattern TP1 may be exposed. For example, the second hard mask HM2 may be removed by a dry etching process or a wet etching process.

Thereafter, a reflection layer RL may be formed on the light blocking patterns BP and the first transmission pattern TP1. For example, the reflection layer RL may be formed by a sputtering process. The reflection layer RL may include a material having relatively low transmittance and absorption and relatively high reflectance. For example, the reflection layer RL may include a metal.

The reflection layer RL may be formed along a profile of the first transmission pattern TP1, the light blocking patterns BP, and the second openings OP2. For example, the reflection layer RL may extend from upper surfaces of the first transmission pattern TP1 and the light blocking patterns BP to lower surfaces of the second openings OP2 along side surfaces SS of the second openings OP2.

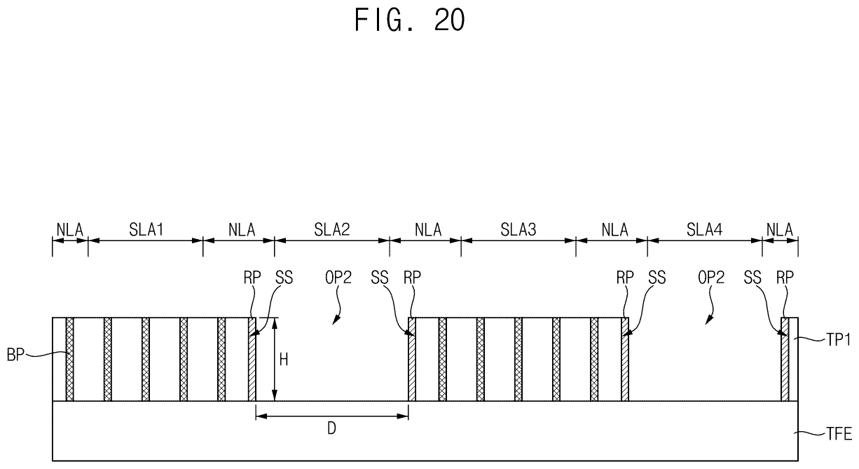

Referring to FIGS. 19 and 20, the reflection layer RL may be patterned. For example, the reflection layer RL may be patterned through a photolithography process.

As the reflection layer RL is etched, the reflection patterns RP may be formed. For example, the reflection patterns RP may be formed through a dry etching process. Each of the reflection patterns RP may be disposed in the second openings OP2. In an embodiment, the reflection patterns RP may at least partially cover the side surfaces SS of the second openings OP2, respectively.

The distance D between the reflection patterns RP may be adjusted in the step of forming the first transmission pattern TP1 defining the second openings OP2, the step of forming the reflection patterns RP, or the like. The height H of the reflection pattern RP may be adjusted in the step of forming the reflection layer RL, the step of forming the reflection patterns RP, or the like.

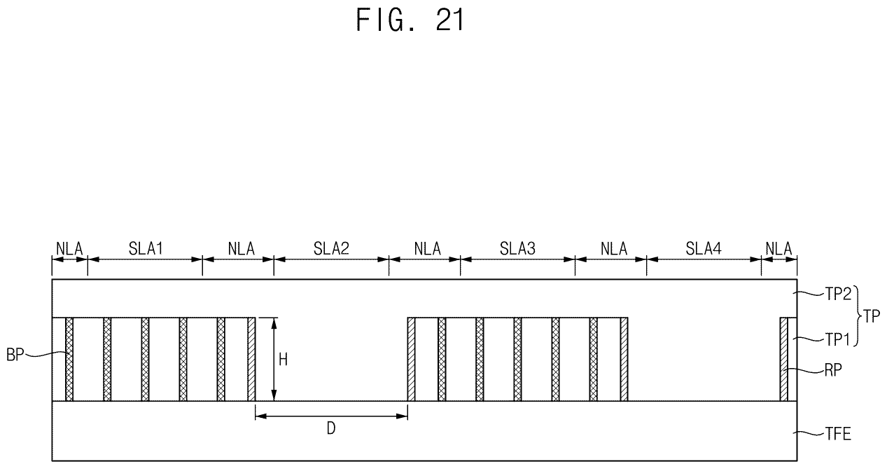

Referring to FIGS. 20 and 21, the second transmission pattern TP2 may be formed on the first transmission pattern TP1. For example, the second transmission pattern TP2 may be formed through a coating process. For example, the second transmission pattern TP2 may be formed through an inkjet process. The second transmission pattern TP2 may fill the second openings OP2, and may cover the upper surface of the first transmission pattern TP1, the upper surfaces of the light blocking patterns BP, and the upper surfaces of the reflection patterns RP. Accordingly, the transmission pattern TP covering the light blocking patterns BP and the reflection patterns RP may be formed.

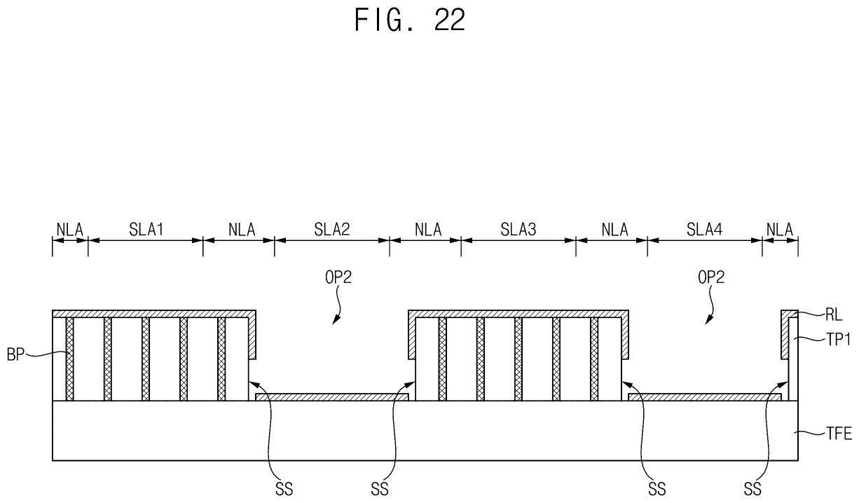

FIGS. 22, 23, and 24 are cross-sectional views illustrating a method of manufacturing a display device, according to an embodiment of the present disclosure.

A method of manufacturing a display device described with reference to FIGS. 22, 23, and 24 may be substantially the same as or similar to the method of manufacturing the display device described with reference to FIGS. 14 to 21 except for shapes of the reflection layer RL and the reflection patterns RP. For example, FIGS. 22, 23, and 24 may correspond to the cross-sectional views of FIGS. 19, 20, and 21, respectively. Hereinafter, to the extent that an element is not described in detail with respect to this figure, it may be understood that the element is at least similar to a corresponding element that has been described elsewhere within the present disclosure.

Referring to FIGS. 3 and 22, the light blocking patterns BP and the first transmission pattern TP1 may be formed on the encapsulation layer TFE, and a reflection layer RL may be formed on the light blocking patterns BP and the first transmission pattern TP1.

For example, the reflection layer RL may be formed through a sputtering process. In this case, the reflection layer RL might not cover the side surfaces SS of the second openings OP2 as a whole. For example, the reflection layer RL may be mainly formed on an upper side of each of the side surfaces SS of the second openings OP2, and may be hardly formed on a lower side of each of the side surfaces SS of the second openings OP2. For example, the reflection layer RL may extend from the upper surfaces of the first transmission pattern TP1 and the light blocking patterns BP to the upper sides of the side surfaces SS of the second openings OP2.

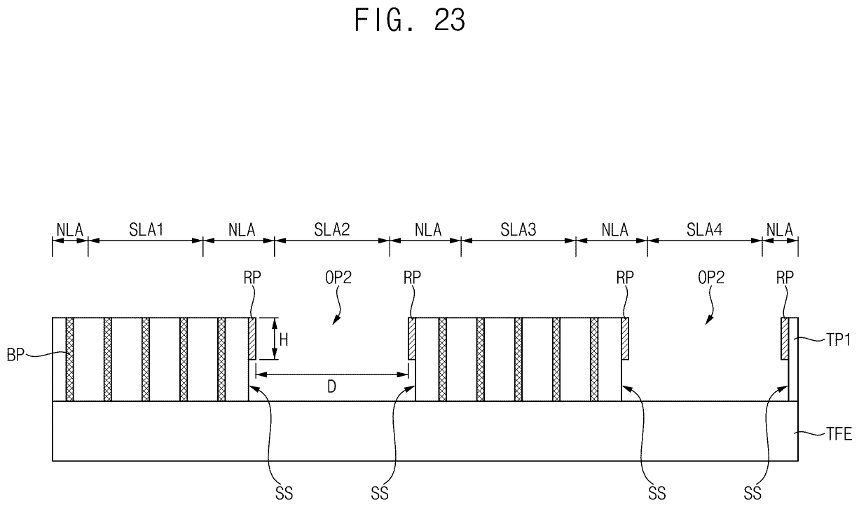

Referring to FIGS. 22 and 23, the reflection layer RL may be patterned, and reflection patterns RP may be formed. Each of the reflection patterns RP may be disposed in the second openings OP2. In an embodiment, the reflection patterns RP may at least partially cover the upper sides of the side surfaces SS of the second openings OP2, respectively.

Since the reflection layer RL is mainly formed on the upper sides of the side surfaces SS of the second openings OP2, the reflection patterns RP having a relatively small height H may be formed. For example, the height H of the reflection pattern RP may be adjusted in the step of forming the reflection layer RL, or the like.

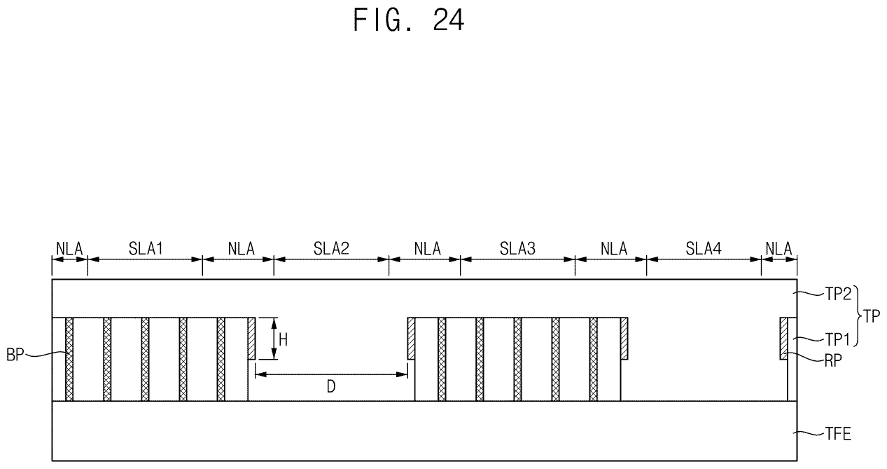

Referring to FIGS. 23 and 24, the second transmission pattern TP2 may be formed on the first transmission pattern TP1, and the transmission pattern TP covering the light blocking patterns BP and the reflection patterns RP may be formed.

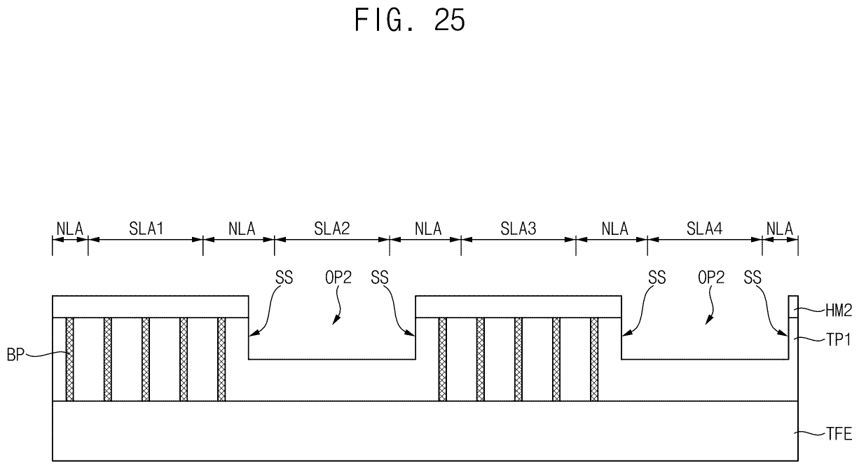

FIGS. 25, 26, 27, and 28 are cross-sectional views illustrating a method of manufacturing a display device, according to an embodiment of the present disclosure.

A method of manufacturing a display device described with reference to FIGS. 25, 26, 27, and 28 may be substantially the same as or similar to the method of manufacturing the display device described with reference to FIGS. 14 to 21 except for shapes of the first transmission pattern TP1, the reflection layer RL, and the reflection patterns RP. For example, FIGS. 25, 26, 27, and 28 may correspond to the cross-sectional views of FIGS. 18, 19, 20, and 21, respectively. Hereinafter, to the extent that an element is not described in detail with respect to this figure, it may be understood that the element is at least similar to a corresponding element that has been described elsewhere within the present disclosure.

Referring to FIGS. 3 and 25, a preliminary transmission pattern (e.g., the preliminary transmission pattern P_TP of FIG. 17), the light blocking patterns, BP and the second hard mask HM2 may be formed on the encapsulation layer TFE, and the preliminary transmission pattern may be patterned to form a first transmission pattern TP1. The first transmission pattern TP1 may define second openings OP2 spaced apart from each other.

In an embodiment, each of the second openings OP2 may be recessed from an upper surface of the first transmission pattern TP1 in a thickness direction of the first transmission pattern TP1. Each of the second openings OP2 might not penetrate the first transmission pattern TP1 in the thickness direction of the first transmission pattern TP1.

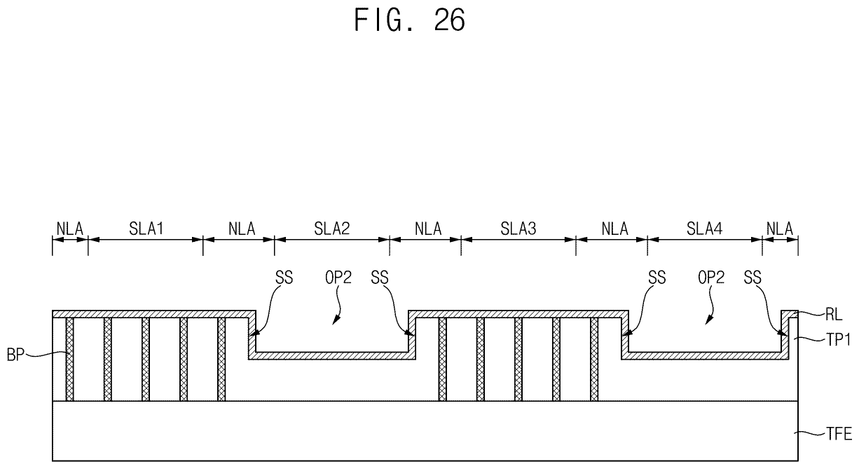

Referring to FIGS. 25 and 26, the second hard mask HM2 may be removed, and a reflection layer RL may be formed on the light blocking patterns BP and the first transmission pattern TP1.

For example, the reflection layer RL may cover side surfaces SS of the second openings OP2 as a whole. The reflection layer RL may be formed along a profile of the first transmission pattern TP1 and the light blocking patterns BP. The reflection layer RL may extend from upper surfaces of the first transmission pattern TP1 and the light blocking patterns BP to lower surfaces of the second openings OP2 along the side surfaces SS of the second openings OP2.

For example, the reflection layer RL may be mainly formed on an upper side of each of the side surfaces SS of the second openings OP2, and may be hardly formed on a lower side of each of the side surfaces SS of the second openings OP2. The reflection layer RL may extend from the upper surfaces of the first transmission pattern TP1 and the light blocking patterns BP to the upper sides of the side surfaces SS of the second openings OP2.

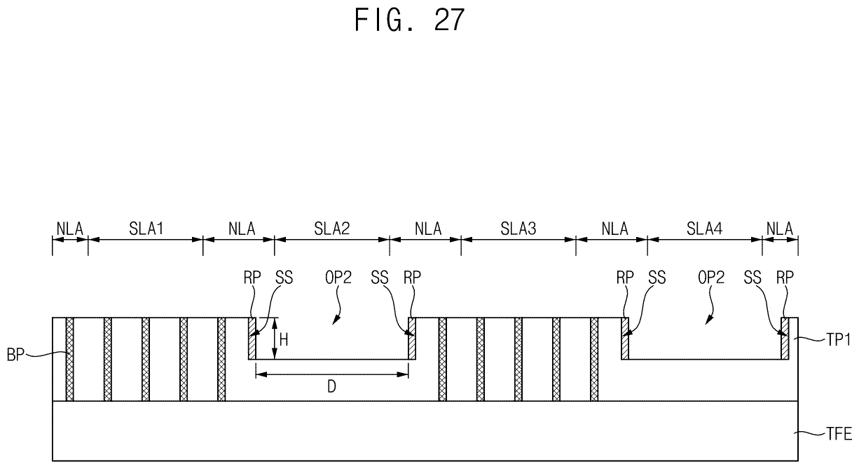

Referring to FIGS. 26 and 27, the reflection layer RL may be patterned to form reflection patterns RP. Each of the reflection patterns RP may be disposed in the second openings OP2. In an embodiment, the reflection patterns RP may at least partially cover the side surfaces SS of the second openings OP2, respectively.

Since each of the second openings OP2 does not penetrate the first transmission pattern TP1 in the thickness direction, the reflection patterns RP having a relatively small height H may be formed. For example, the height H of the reflection pattern RP may be adjusted in the step of forming the second openings OP2 to form the first transmission pattern TP1, or the like.

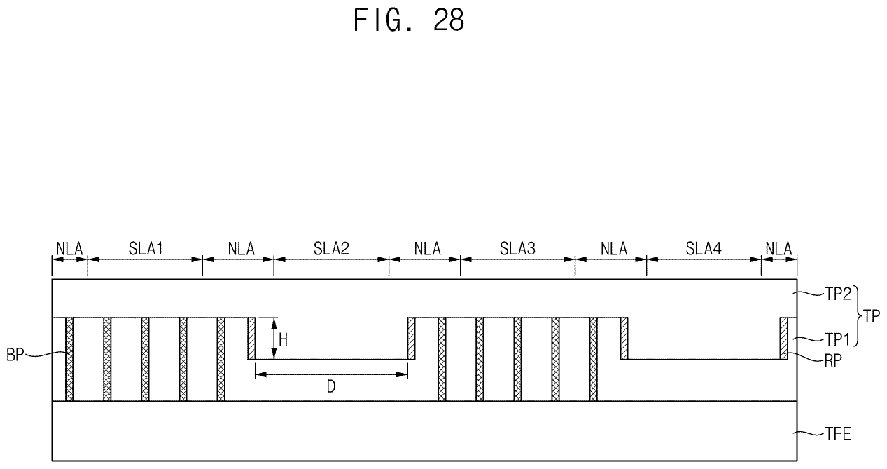

Referring to FIGS. 27 and 28, the second transmission pattern TP2 may be formed on the first transmission pattern TP1, and the transmission pattern TP covering the light blocking patterns BP and the reflection patterns RP may be formed.

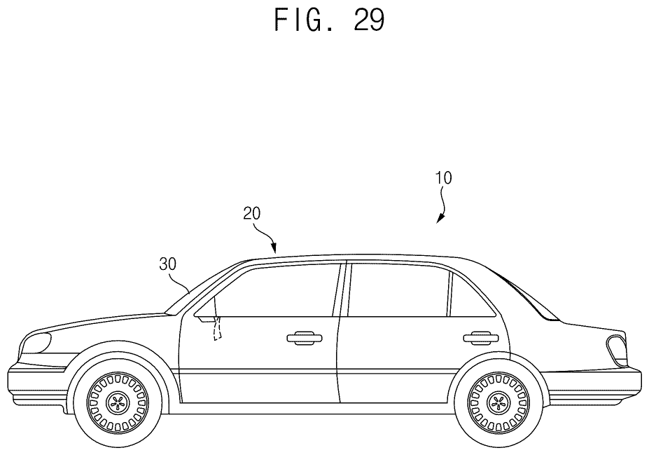

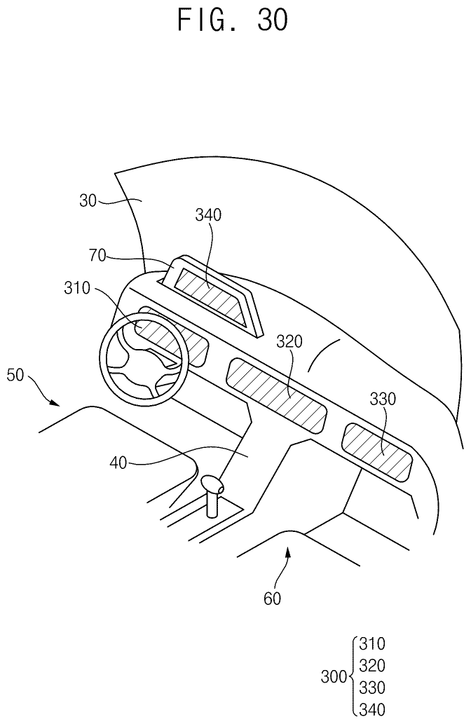

FIG. 29 is a view schematically illustrating an exterior of a vehicle, according to an embodiment of the present disclosure. FIG. 30 is a view schematically illustrating an interior of the vehicle of FIG. 29.

Referring to FIGS. 29 and 30, a vehicle 10 may include a vehicle body 20 and a display device 300. The vehicle body 20 may form an exterior of the vehicle 10, and may define an interior space in which a driver and a passenger ride. The vehicle body 20 may include a front window glass 30 that protects the driver and the passenger from outside and provides a view to the driver. The display device 300 may be disposed in the interior space. For example, the display device 300 may correspond to the display device DD described with reference to FIGS. 1 to 13. For example, the display device 300 may have a structure substantially the same as or similar to that of the display device DD described with reference to FIGS. 1 to 13.

The display device 300 may include first, second, third, and fourth display areas 310, 320, 330, and 340. For example, the first, second, and third display areas 310, 320, and 330 may be disposed on a dashboard 40 provided in the interior space.

For example, the first display area 310 may disposed on the dashboard 40 in front of a driver's seat 50 to provide speed information or the like to the driver, the second display area 320 may be disposed on a center of the dashboard 40 to provide map information or the like, and the third display area 330 may be disposed on the dashboard 40 in front of a passenger's seat 60 to provide entertainment information or the like to the passenger.

In addition, the fourth display area 340 may be included in a head-up display 70. The head-up display 70 may be disposed on the dashboard 40. For example, the fourth display area 340 may provide information helpful for driving or the like to the driver.

For example, the first, second, and third display areas 310, 320, and 330 may be included in a single display device. In this case, the fourth display area 340 may be included in a separate display device different from the first, second, and third display areas 310, 320, and 330. For example, all of the first, second, third, and fourth display areas 310, 320, 330, and 340 may be included in a single display device. However, embodiments are not necessarily limited thereto.

At least one of the first, second, third, and fourth display areas 310, 320, 330, and 340 may adjust a viewing angle depending on a mode. For example, at least one of the first, second, third, and fourth display areas 310, 320, 330, and 340 may display an image in a wide viewing angle mode or a narrow viewing angle mode.

For example, when describing based on the third display area 330, the wide viewing angle mode may mean a state in which a viewing angle of the third display area 330 is wide, and the narrow view viewing angle mode may mean a state in which a viewing angle of the third display area 330 is narrow. In the wide viewing angle mode, an image may be displayed not only to the passenger sitting in the passenger's seat 60 but also to the driver sitting in the driver's seat 50. Accordingly, both the passenger and the driver may check the image of the third display area. In contrast, in the narrow viewing angle mode, an image may be displayed only to the passenger sitting in the passenger's seat 60, and the image might not be displayed to the driver sitting in the driver's seat 50. Accordingly, only the passenger may check the image of the third display area 330.

Although FIG. 30 illustrates that the display device 300 is disposed on the dashboard 40, embodiments are not necessarily limited thereto. For example, the display device 300 may be variously disposed in the vehicle 10, such as being disposed on the front window glass 30.

In addition, the display device DD, according to embodiments of the present disclosure, is not necessarily limited to being applied only to the display device 300 disposed in the vehicle 10 of FIGS. 29 and 30, and may be applied to various display devices.

The display device DD according to embodiments of the present disclosure may be applied to various electronic devices. An electronic device according to an embodiment of the present disclosure may include the display device DD described above, and may further include a module or device having additional functions in addition to the display device DD.

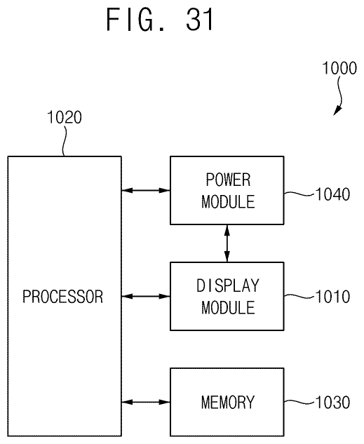

FIG. 31 is a block diagram illustrating an electronic device according to an embodiment of the present disclosure.

Referring to FIG. 31, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module that converts power supplied by the power supply module to generate power necessary for an operation of the electronic device 1000.

At least one of the components of the electronic device 1000 described above may be included in the display device according to embodiments described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000 other than the display device.

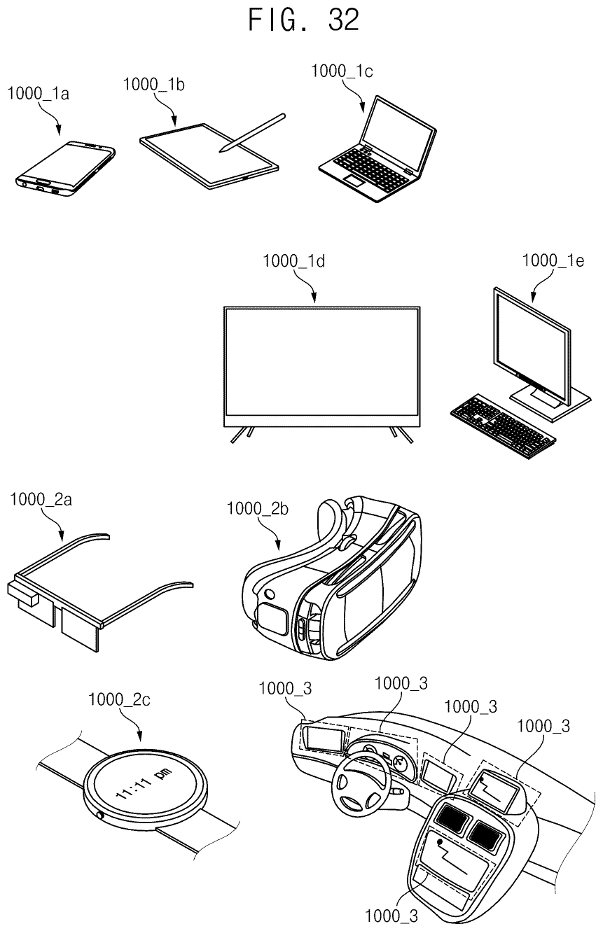

FIG. 32 is a schematic diagram of an electronic device according to embodiments of the present disclosure.

Referring to FIG. 32, various electronic devices to which the display device according to embodiments of the present disclosure are applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not necessarily to be construed as limiting thereof. Although a few embodiments have been described, those skilled in the art will readily appreciate that many modifications are possible in the embodiments without materially departing from the novel teachings and aspects of the present inventive concept. Accordingly, all such modifications are intended to be included within the scope of the present inventive concept.

What is claimed is:

1. A display device, comprising:
a substrate including:
a light emitting area including a first sub-light emitting area and a second sub-light emitting area adjacent to the first sub-light emitting area; and
a non-light emitting area adjacent to the light emitting area;
a light emitting element disposed on the substrate and including:
a first sub-light emitting element disposed in the first sub-light emitting area; and
a second sub-light emitting element disposed in the second sub-light emitting area;
light blocking patterns disposed in the first sub-light emitting area, on the light emitting element; and
reflection patterns disposed adjacent to the second sub-light emitting area, on the light emitting element.

2. The display device of claim 1, wherein the light blocking patterns overlap the first sub-light emitting area and the non-light emitting area in a plan view, and do not overlap the second sub-light emitting area in the plan view.

3. The display device of claim 1, wherein the reflection patterns do not overlap the first sub-light emitting area in a plan view, and overlap the non-light emitting area in the plan view.

4. The display device of claim 3, wherein the reflection patterns overlap an edge of the second sub-light emitting area in the plan view.

5. The display device of claim 1, wherein a distance between an adjacent pair of reflection patterns, of the reflection patterns, with the second sub-light emitting area interposed therebetween is greater than or equal to a width of the second sub-light emitting area.

6. The display device of claim 1, wherein each of the reflection patterns contact a closest one of the light blocking patterns.

7. The display device of claim 1, further comprising:
a transmission pattern covering the light blocking patterns and the reflection patterns.

8. The display device of claim 7, wherein the transmission pattern includes:
a first transmission pattern filling a space between the light blocking patterns disposed adjacent to each other and defining openings in which the reflection patterns are disposed; and
a second transmission pattern disposed on the first transmission pattern and filling the openings.

9. The display device of claim 8, wherein each of the reflection patterns at least partially cover side surfaces of a respective one of the openings.

10. The display device of claim 8, wherein a height of each of the reflection patterns is less than or equal to a height of the first transmission pattern.

11. The display device of claim 8, wherein a level of an upper surface of each of the reflection patterns is equal to a level of an upper surface of the first transmission pattern.

12. The display device of claim 1, wherein the light blocking patterns and the reflection patterns include different materials.

13. The display device of claim 1, wherein the first sub-light emitting area and the second sub-light emitting area emit light of a same wavelength band.

14. A method of manufacturing a display device, comprising:
forming a light emitting element on a substrate, the substrate including a light emitting area including a first sub-light emitting area and a second sub-light emitting area adjacent to the first sub-light emitting area, and a non-light emitting area adjacent to the light emitting area, wherein the light emitting element includes a first sub-light emitting element disposed in the first sub-light emitting area and a second sub-light emitting element disposed in the second sub-light emitting area;
forming a transmission layer on the light emitting element;
patterning the transmission layer to form a preliminary transmission pattern, the preliminary transmission pattern defining first openings in the first sub-light emitting area;
forming light blocking patterns filling the first openings, respectively;
patterning the preliminary transmission pattern to form a first transmission pattern, the first transmission pattern defining a second opening in the second sub-light emitting area; and
forming reflection patterns at least partially covering side surfaces of the second opening, respectively.

15. The method of claim 14, wherein the light blocking patterns overlap the first sub-light emitting area and the non-light emitting area and do not to overlap the second sub-light emitting area, in a plan view.

16. The method of claim 14, wherein the reflection patterns do not overlap the first sub-light emitting area and overlap the non-light emitting area, in a plan view.

17. The method of claim 16, wherein the reflection patterns overlap an edge of the second sub-light emitting area, in the plan view.

18. The method of claim 14, wherein a distance between an adjacent pair of the reflection patterns, with the second sub-light emitting area interposed therebetween, is greater than or equal to a width of the second sub-light emitting area.

19. The method of claim 14, wherein the reflection patterns contact the light blocking patterns that are most adjacent, respectively.

20. The method of claim 14, wherein a height of each of the reflection patterns is less than or equal to a height of the first transmission pattern.

21. The method of claim 14, wherein a level of an upper surface of each of the reflection patterns is equal to a level of an upper surface of the first transmission pattern.

22. The method of claim 14, further comprising:
forming a second transmission pattern filing the second opening and covering the light blocking patterns, the reflective patterns, and the first transmission pattern.

23. The method of claim 14, wherein the first sub-light emitting area and the second sub-light emitting area emit light of a same wavelength band.

24. An electronic device, comprising:
a display device; and
a power module that supplies power to the display device,
wherein the display device includes:
a substrate including:
a light emitting area including a first sub-light emitting area and a second sub-light emitting area adjacent to the first sub-light emitting area; and
a non-light emitting area adjacent to the light emitting area;
a light emitting element disposed on the substrate and including:
a first sub-light emitting element disposed in the first sub-light emitting area; and
a second sub-light emitting element disposed in the second sub-light emitting area;
light blocking patterns disposed in the first sub-light emitting area, on the light emitting element; and
reflection patterns disposed adjacent to the second sub-light emitting area, on the light emitting element.
